(19) United States
(12) Patent Application Publication
(10) Pub. No.: US 2026/0171990 A1
(43) Pub. Date: Jun. 18, 2026

(54) METHODS AND APPARATUS TO AMPLIFY SIGNALS USING AMPLIFIER CIRCUITRY

(71) Applicant: Texas Instruments Incorporated, Dallas, TX (US)

(72) Inventors: Ravikumar Pattipaka, Bangalore (IN); Raja Sekhar, Bangalore (IN); Savyan Kanisserry, Bangalore (IN); Vajeed Nimran, Bangalore (IN)

(21) Appl. No.: 19/222,610

(22) Filed: May 29, 2025

(30) Foreign Application Priority Data
Dec. 18, 2024 (IN) 202441100224

(51) Int. Cl. H03F 3/45; H03F 1/32

(52) U.S. Cl. CPC H03F 3/45475; H03F 1/3211

(57) ABSTRACT

An example apparatus includes: transconductance circuitry having an input and an output; a first capacitor having a terminal; an amplifier having an input and an output, the input of the amplifier coupled to the output of the transconductance circuitry and the terminal of the first capacitor; a resistor having a first terminal and a second terminal; and a second capacitor having a first terminal and a second terminal, the first terminal of the second capacitor coupled to the output of the amplifier and the first terminal of the resistor, the second terminal of the second capacitor coupled to the input of the transconductance circuitry and the second terminal of the resistor.

### CROSS-REFERENCE TO RELATED APPLICATION

This patent application claims the benefit of and priority to IN Provisional Patent Application No. 202441100224 filed Dec. 18, 2024, which is hereby incorporated herein by reference in its entirety.

### TECHNICAL FIELD

This description relates generally to amplifiers and, more particularly, to methods and apparatus to amplify signals using amplifier circuitry.

### BACKGROUND

Amplifier circuitry amplifies an input signal by a gain. Amplifiers may be used for a wide range of functions, such as modulation, buffering, transmission, etc. Some amplifier circuitry includes a feedback loop between an input and an output to set the gain, improve stability, etc. Such an amplifier circuitry configuration is referred to as a closed-loop amplifier. Closed-loop amplifiers produce an output voltage based on a difference (also referred to as error) between an input voltage and a output voltage.

### SUMMARY

For methods and apparatus to amplify signals using amplifier circuitry, an example apparatus includes transconductance circuitry having an input and an output; a first capacitor having a terminal; an amplifier having an input and an output, the input of the amplifier coupled to the output of the transconductance circuitry and the terminal of the first capacitor; a resistor having a first terminal and a second terminal; and a second capacitor having a first terminal and a second terminal, the first terminal of the second capacitor coupled to the output of the amplifier and the first terminal of the resistor, the second terminal of the second capacitor coupled to the input of the transconductance circuitry and the second terminal of the resistor. Other examples are described.

For methods and apparatus to amplify signals using amplifier circuitry, an example apparatus includes transconductance circuitry having an input and an output; a first capacitor having a terminal; an amplifier having an input and an output, the input of the amplifier coupled to the output of the transconductance circuitry and the terminal of the first capacitor; a first resistor having a first terminal and a second terminal, the first terminal of the first resistor coupled to the output of the amplifier; a second resistor having a terminal; a third resistor having a first terminal and a second terminal, the first terminal of the third resistor coupled to the input of the transconductance circuitry, the second terminal of the first resistor, and the terminal of the second resistor; and a second capacitor having a terminal coupled to the second terminal of the third resistor. Other examples are described.

For methods and apparatus to amplify signals using amplifier circuitry, an example apparatus includes transconductance circuitry having an input and an output; an amplifier having an input and an output, the input of the amplifier coupled to the output of the transconductance circuitry; a first resistor having a first terminal and a second terminal; a first capacitor having a first terminal and a second terminal, the first terminal of the first capacitor coupled to the output of the amplifier and the first terminal of the first resistor; a second resistor having a first terminal and a second terminal, the first terminal of the second resistor coupled to the input of the transconductance circuitry, the second terminal of the first resistor, and the second terminal of the first capacitor; and a second capacitor having a terminal coupled to the second terminal of the second resistor. Other examples are described.

### BRIEF DESCRIPTION OF THE DRAWINGS

FIG. 1 is a block diagram of an example ultrasound system including example amplifier circuitry and an example controller.

FIG. 2 is a schematic diagram of an example of the amplifier circuitry of FIG. 1.

FIG. 3 is a schematic diagram of another example of the amplifier circuitry of FIGS. 1 and 2.

FIG. 4 is a schematic diagram of yet another example of the amplifier circuitry of FIGS. 1, 2, and 3.

FIG. 5 is a block diagram of an example of the controller of FIG. 1.

FIG. 6 is a flowchart representative of example machine-readable instructions or example operations that may be at least one of executed, instantiated, or performed using an example implementation of the amplifier circuitry of FIGS. 1, 2, 3, and 4 and the controller of FIGS. 1 and 5 or more generally the ultrasound system of FIG. 1.

FIG. 7 is a flowchart representative of example machine-readable instructions or example operations that may be at least one of executed, instantiated, or performed using an example implementation of the controller of FIGS. 1 and 5 to calibrate the amplifier circuitry of FIGS. 1, 2, 3, and 4 for first voltage swing conditions.

FIGS. 8A and 8B are plots of example calibration operations of FIG. 7 for the amplifier circuitry of FIGS. 1, 2, 3, and 4.

FIG. 9 is a flowchart representative of example machine-readable instructions or example operations that may be at least one of executed, instantiated, or performed using an example implementation of the controller of FIGS. 1 and 5 to calibrate the amplifier circuitry of FIGS. 1, 2, 3, and 4 for second voltage swing conditions.

FIG. 10 is a plot of example calibration operations of FIG. 9 for the amplifier circuitry of FIGS. 1, 2, 3, and 4.

FIG. 11 is a block diagram of an example processing platform including programmable circuitry structured to execute, instantiate, or perform the example machine-readable instructions or perform the example operations of FIGS. 6, 7, and 9 to implement the controller of FIGS. 1 and 5.

FIG. 12 is a block diagram of an example implementation of the programmable circuitry of FIG. 11.

FIG. 13 is a block diagram of another example implementation of the programmable circuitry of FIG. 11.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Amplifier circuitry amplifies an input signal by a gain. Amplifiers may be used for a wide range of functions, such as modulation, buffering, transmission, etc. Some amplifier circuitry includes a feedback loop between an input and an output to set the gain, improve stability, etc. Such an amplifier circuitry configuration is referred to as a closed-loop amplifier. Closed-loop amplifiers produce an output voltage based on a difference (also referred to as error) between an input voltage and a output voltage.

In some devices, such ultrasound devices, amplifier circuitry may experience a wide range of operating conditions. For example, during ultrasonic imaging, transducers transmit signals at ultrasonic frequencies (frequencies beyond the audible spectrum) responsive to receiving electrical signals from amplifier circuitry. In such examples, the amplifier circuitry operates across a relatively wide bandwidth, such as 15 to 25 megahertz (MHz), and relatively wide range of voltage swings, such as +/−5 volts (V) to +/−100 volts. Such wide voltage and frequency ranges increase power consumption and negatively impacts loop stability in closed loop amplifiers. Also, in medical devices, tolerances of the amplifier circuitry are limited by regulatory or industry standards. As electronics continue to advance, amplifier circuitry needs to support an increasing bandwidth and increasing output voltages.

Examples described herein include methods and apparatus to amplify signals using amplifier circuitry. In some described examples, amplifier circuitry includes transconductance circuitry, a capacitor, a buffer, feedback resistor-capacitor (RC) circuitry, an input resistor, and pole-zero pair circuitry. The transconductance circuitry determines an error current (IE) using an input voltage (V_{IN}) and an error voltage (V_{E}). The transconductance circuitry amplifies the error current according to a transconductance constant (K). The capacitor produces an output voltage (V_{OUT}) by converting the amplified error current to a voltage. The buffer provides the output voltage to the feedback RC circuitry and the output of the amplifier circuitry. The feedback RC circuitry filters out relatively high frequencies from the output voltage. The feedback RC circuitry and the input resistor produce a feedback current (I_{F}) responsive to the output voltage. The zero-pole pair circuitry and the input resistor produce the error voltage responsive to the feedback current and the error current. Advantageously, the output voltage of the amplifier circuitry is proportional to the difference between the input voltage (V_{IN}) and the error voltage (V_{E}), which is a function of the output voltage (V_{OUT}).

In some described examples, the amplifier circuitry is coupled to a controller. The controller provides trim values to set components of the amplifier circuitry. For example, the controller provides a first trim value to set the transconductance constant (K) of the transconductance circuitry and a second trim value to set a capacitance (C_{F}) of the feedback RC circuitry. In example operations, if the gain of the amplifier circuitry is near unity (e.g., a gain of 1), the controller adjusts the transconductance constant and the capacitance (C_{F}) to produce relatively low output voltages. In such example unity gain operations, the transconductance factor controls the magnitude response, which sets the bandwidth, and the feedback RC circuitry adjusts a non-dominant pole of the open-loop gain to a lower frequency. For relatively low voltages, such as voltages less than twenty volts peak-to-peak (Vₚₚ), the non-dominant pole of the feedback circuitry modifies the phase margin of the amplifier circuitry. Advantageously, the controller may calibrate the bandwidth and phase margin of the amplifier circuitry using the transconductance constant and the capacitance of the feedback RC circuitry.

In example operations, if the gain of the amplifier circuitry is not near unity, such as being a relatively high gain, the controller adjusts the transconductance constant and the zero-pole pair circuitry to produce relatively high voltages. In such example non-unity gain operations, the transconductance factor sets the gain of the transconductance circuitry and the zero-pole pair circuitry modifies the closed loop gain of the amplifier circuitry. For relatively high voltages, such as voltages greater than twenty volts peak-to-peak, the non-dominant pole of the open-loop gain moves away from the unity gain frequency. In such conditions, shifting the non-dominant pole of the open-loop gain overdamps the amplifier circuitry. However, the zero-pole pair circuitry includes a resistance in parallel with the input resistor. The relationship between a resistance (R_{Z}) of the zero-pole pair circuitry and a resistance (R_{IN}) of the input resistor produces a factor that modifies the error voltage. Such a relationship is illustrated by the closed-loop gain equation further illustrated and described below. At relatively high voltage swing conditions, adjusting the resistance of the zero-pole pair circuitry shifts the frequency response of the amplifier circuitry based on the relationship between the input resistor and the zero-pole pair circuitry. Advantageously, the controller may calibrate the closed loop bandwidth of the amplifier circuitry at non-unity gains using the zero-pole pair circuitry. Example operations of the amplifier circuitry and the controller are further illustrated and described below.

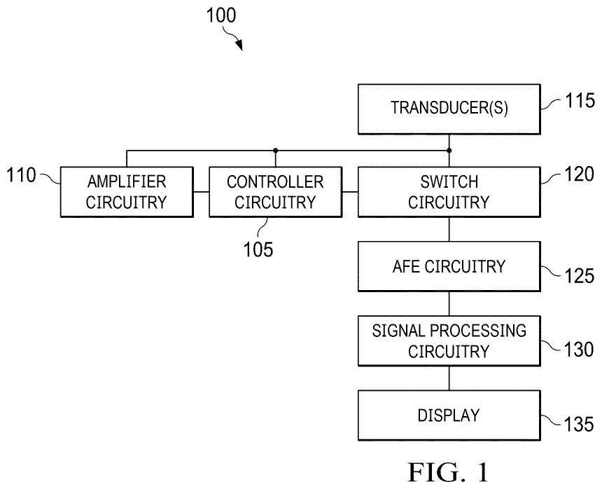

FIG. 1 is a block diagram of an example ultrasound system 100. The example ultrasound system 100 of FIG. 1 includes an example controller 105, example amplifier circuitry 110, example transducer(s) 115, example switch circuitry 120, example analog front end (AFE) circuitry 125, example signal processing circuitry 130, and an example display 135. The ultrasound system 100 uses soundwaves to produce images. Unlike audible soundwaves, the ultrasound system 100 produces soundwaves in the ultrasonic frequency range, which are not audible frequencies.

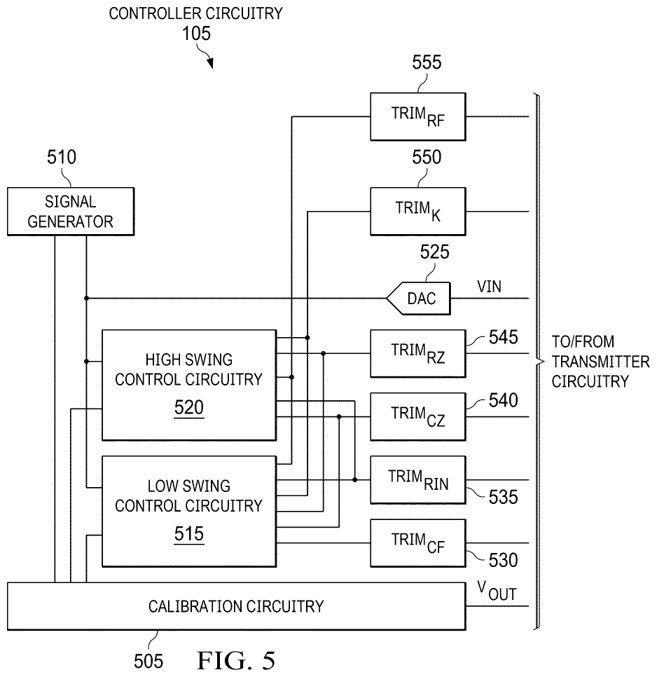

The controller 105 controls transmission of ultrasonic waves. The controller 105 provides a relatively low power representation of an ultrasonic signal to the amplifier circuitry 110. An example of the controller 105 is further illustrated and described in connection with FIG. 5.

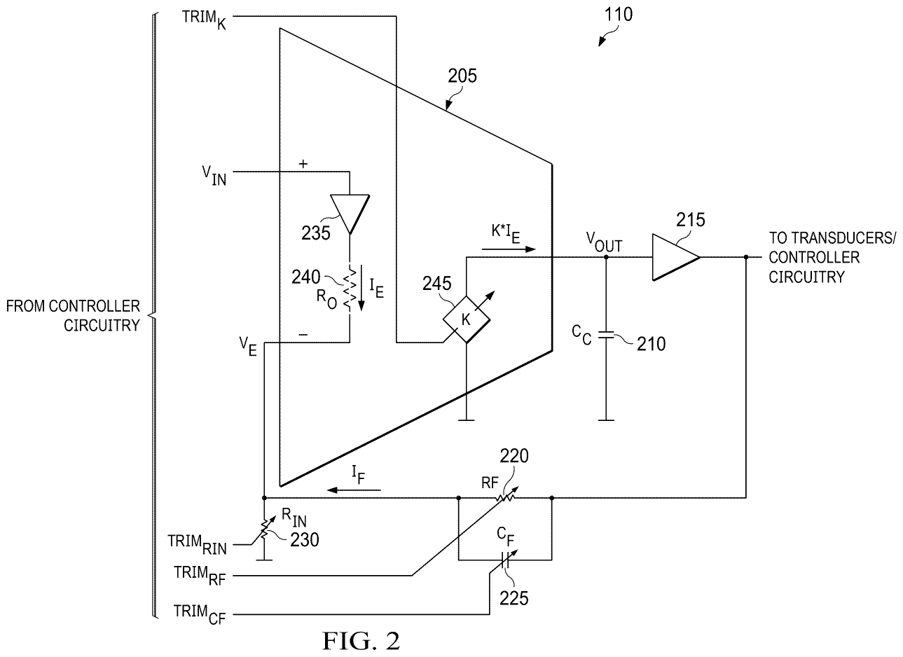

The amplifier circuitry 110 produces an ultrasonic signal responsive to the signal from the controller 105. In some examples, the amplifier circuitry 110 is referred to as transmitter circuitry. Examples of the amplifier circuitry 110 are further illustrated and described in connection with FIGS. 2, 3, and 4.

The transducer(s) 115 transmit the ultrasonic signals from the amplifier circuitry 110. In some examples, the transducer(s) 115 are positioned to direct the propagation of the ultrasonic signals. The ultrasonic signals propagate through a medium responsive to positioning the transducer(s) 115. In example ultrasonic imaging, objects of the medium produce reflections responsive to the ultrasonic signals. The transducer(s) 115 receive the reflections of the ultrasonic signal.

The switch circuitry 120 provides reflected signals from the transducer(s) 115 to the AFE circuitry 125. The switch circuitry 120 prevents the AFE circuitry 125 from receiving ultrasonic signals from the amplifier circuitry 110. For example, if the transducer(s) 115 are transmitting ultrasonic signals, the switch circuitry 120 disconnects the AFE circuitry 125 from the transducer(s) 115. In such examples, the switch circuitry 120 connects the AFE circuitry 125 to the transducer(s) 115 after the transmission is complete.

The AFE circuitry 125 receives reflected signals from the transducers 115. The AFE circuitry 125 converts the reflected signals from analog to digital. In some examples, the AFE circuitry 125 conditions the reflected signals, such as filtering frequencies outside of the ultrasonic frequency range. The AFE circuitry 125 provides a digital representation of the reflected signals to the signal processing circuitry 130.

The signal processing circuitry 130 processes data of the reflected signals to form an image of the medium traversed by the ultrasonic signals. In some examples, the signal processing circuitry 130 uses beamforming to construct an image using the reflected signals. In other examples, the signal processing circuitry 130 may use one or more fast Fourier transforms (FFTs) to produce ultrasound data, which may be further processed.

The display 135 displays the image from the signal processing circuitry 130. In some examples, the display 135 is communicatively coupled to the signal processing circuitry 130 by a communication interface. For example, the display 135 may be a smartphone connected by Bluetooth to the signal processing circuitry 130. Alternatively, the ultrasound system 100 may not include a display 135. In such examples, the ultrasound system 100 may store the images in a datastore for later analysis.

FIG. 2 is a schematic diagram of an example of the amplifier circuitry 110 of FIG. 1. In the example of FIG. 2, the amplifier circuitry 110 includes example transconductance circuitry 205, a first example capacitor 210, an example buffer 215, a first example resistor 220, a second example capacitor 225, and a second example resistor 230. The example transconductance circuitry 205 of FIG. 2 includes an example buffer 235, an example resistor 240, and example current source circuitry 245.

The amplifier circuitry 110 receives an input voltage (V_{IN}), a transconductance trim value (TRIM_{K}), an input trim value (TRIM_{RIN}), a feedback resistor trim value (TRIM_{RF}), and a capacitor trim value (TRIM_{CF}). In some examples, the controller 105 provides the input voltage and trim values. The input voltage (V_{IN}) represents an ultrasonic signal for transmission. The transconductance trim value (TRIM_{K}) sets a transconductance factor (K) of the transconductance circuitry 205. The transconductance factor (K) corresponds to a gain of the transconductance circuitry 205. The input trim value (TRIM_{RIN}) sets a resistance (R_{IN}) of the resistor 230. The feedback resistor trim value (TRIM_{RF}) set a resistance (R_{F}) of the resistor 220. The capacitor trim value (TRIM_{CF}) sets a capacitance (C_{F}) of the capacitor 225. The amplifier circuitry 110 produces an output signal (V_{OUT}) using the input voltage (V_{IN}).

The transconductance circuitry 205 receives the input voltage (V_{IN}), the transconductance trim value (TRIM_{K}), and an error voltage (V_{E}). The error voltage (V_{E}) is a voltage proportional to a feedback current (I_{F}) times the resistance (R_{IN}) of the resistor 230. The transconductance circuitry 205 produces an amplified error current (K*I_{E}) responsive to the input voltage (V_{IN}), the transconductance trim value (TRIM_{K}), and the error voltage (V_{E}).

In example operation of the transconductance circuitry 205, the buffer 235 buffers the input voltage (V_{IN}) to isolate the resistor 240 from the input of the amplifier circuitry 110. In some examples, such an isolation using the buffer 235 sets the input of the amplifier circuitry 110 to a relatively high-impedance. The resistor 240 divides a voltage difference between the input signal (V_{IN}) and the error voltage (V_{E}). The resistor 240 produces an error current (I_{E}) based on the voltage difference and a resistance (R_{O}) of the resistor 240. In the example of FIG. 2, as illustrated by the dashed lines, the resistor 240 is an illustrative representation of a look-in impedance of the transconductance circuitry 205. In some examples, the resistor 240 may not be illustrated.

In such an example operation of the transconductance circuitry 205, the current source circuitry 245 amplifies the error current (I_{E}) by the transconductance factor (K). The transconductance trim value (TRIM_{K}) sets the transconductance factor (K) of the current source circuitry 245. In some examples, the amplifier circuitry 110 includes additional circuitry to amplify the error current (I_{E}). In such examples, the current source circuitry 245 mirrors the error current (I_{E}) and the additional circuitry applies the transconductance factor (K) to produce the amplified error current (K*I_{E}). The transconductance circuitry 205 provides the amplified error current (K*I_{E}) to the capacitor 210 and the buffer 215.

The capacitor 210 receives the amplified error current (K*I_{E}) from the transconductance circuitry 205. The capacitor 210 produces an output voltage (V_{OUT}) responsive to the amplified error current (K*I_{E}). In example operations, the output voltage (V_{OUT}) is proportional to the amplified error current (K*I_{E}) and inversely proportional to a capacitance (C_{C}) of the capacitor 210. In such examples, the capacitor 210 converts the amplified error current (K*I_{E}) to the output voltage (V_{OUT}).

The buffer 215 receives the output voltage (V_{OUT}) from the capacitor 210. The buffer 215 buffers the output voltage (V_{OUT}). In example operations, the buffer 215 isolates the capacitor 210 from circuitry coupled to the output of the amplifier circuitry 110. The buffer 215 provides the output voltage (V_{OUT}) to the resistor 220, the capacitor 225, and the transducer(s) 115 of FIG. 1.

The resistor 220 and the capacitor 225 receive the output voltage (V_{OUT}). In some examples, the resistor 220 and the capacitor 225 are referred to as feedback RC circuitry. The resistor 220 and the capacitor 225 form a low pass filter. In example operations, a resistance (RF) of the resistor 220 and a capacitance (C_{F}) of the capacitor 225 control the cut-off frequency of the filter. In some examples, the feedback resistor trim value (TRIM_{RF}) sets the resistance of the resistor 220 and the capacitor trim value (TRIM_{CF}) sets the capacitance of the capacitor 225. The resistor 220 and the capacitor 225 produces the feedback current (I_{F}) by filtering the output voltage (V_{OUT}).

The resistor 230 receives the feedback current (I_{F}) from the resistor 220 and the capacitor 225. The resistor 230 produces the error voltage (V_{E}) using the feedback current (I_{F}) and the resistance (R_{IN}) of the resistor 230. In some examples, the input trim value (TRIM_{RIN}) sets the resistance (R_{IN}) of the resistor 230.

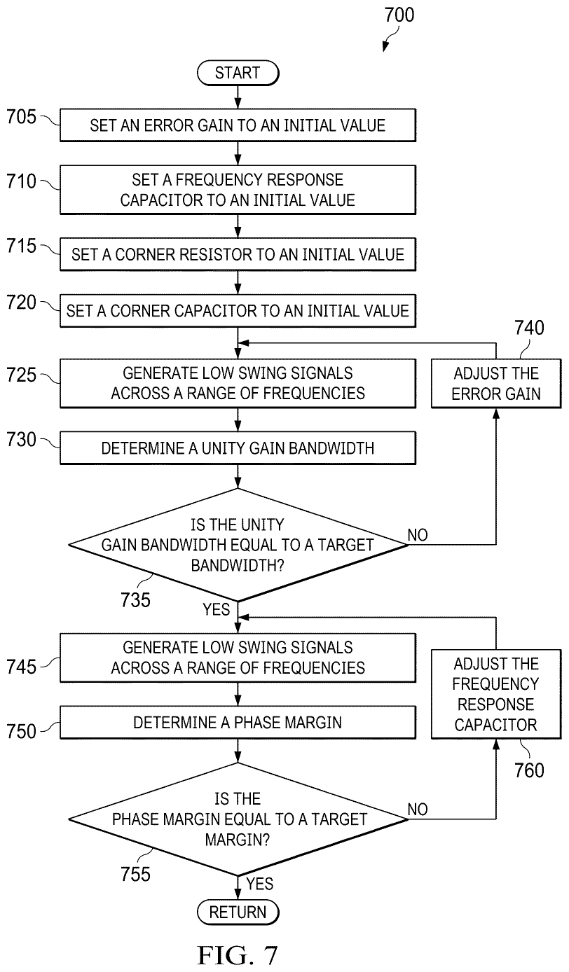

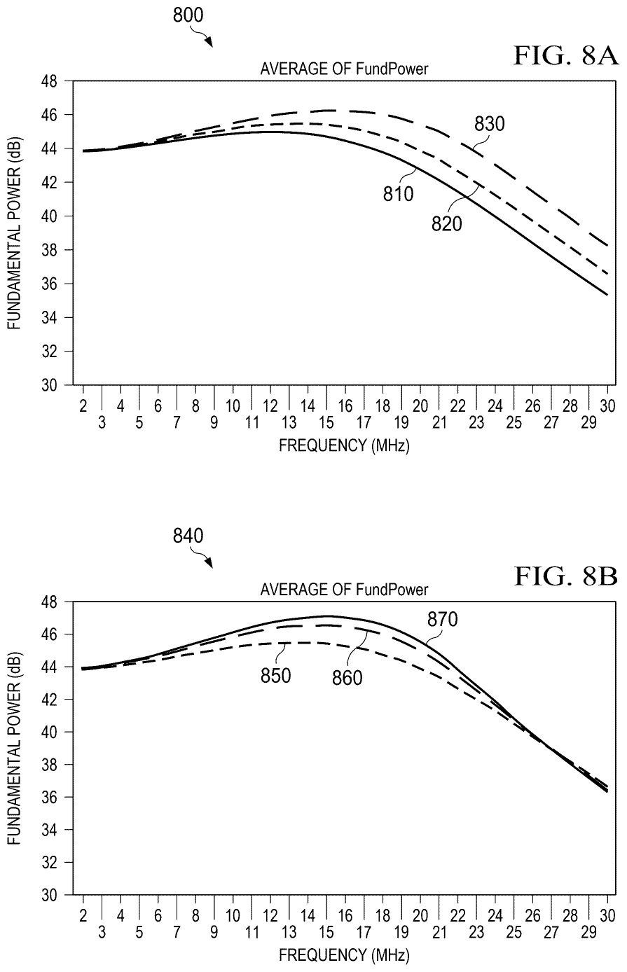

In some devices, such as medical systems, the controller 105 of FIG. 1 calibrates the amplifier circuitry 110 to support increasing bandwidths. During such calibrations, which are further illustrated and described in connection with FIGS. 7, 8A, and 8B, the controller 105 modifies the transconductance trim value (TRIM_{K}), input trim value (TRIM_{RIN}), the feedback resistor trim value (TRIM_{R}F), and the capacitor trim value (TRIM_{CF}) to adjust the bandwidth of the amplifier circuitry 110. In the example of FIG. 2, the amplifier circuitry 110 has an open-loop gain (LG_{OP}) based on the transconductance constant (K), the capacitance (C_{C}) of the capacitor 210, the resistance (R_{F}) of the resistor 220, the capacitance (C_{F}) of the capacitor 225, the resistance (R_{IN}) of the resistor 230, and the resistance (R_{O}) of the resistor 240. In some examples, Equation (1) represents the open-loop gain of the amplifier circuitry 110 across different frequencies (s).

$$OPEN LOOP GAIN = {LG}_{OP} = \frac{K}{{sC}_{C}} * \frac{1 + {sC}_{F} {R}_{F}}{{R}_{F}} * \frac{{R}_{IN}}{{R}_{IN} + {R}_{O}} ; \qquad Equation ( 1 )$$

In some examples, such as medical implementations, a phase margin of the amplifier circuitry 110 is calibrated to account for process variations. Advantageously, the gain of the low pass filter of the resistor 220 and the capacitor 225 form an additional zero in the open-loop gain Equation (1). Advantageously, the additional zero of the resistor 220 and the capacitor 225 allows the open-loop gain of the amplifier circuitry 110 to be adjusted to account for process variations. Advantageously, for relatively low voltage swings, such as near unity, the phase margin is a function of the non-dominant poles. In example operations, the capacitance of the capacitor 225 changes the phase margin of the amplifier circuitry 110. Advantageously, the controller 105 may compensate for variations in phase margins using the capacitor trim value (TRIM_{CF}).

Also, in some examples, such as medical implementations, a magnitude response of the amplifier circuitry 110 is calibrated to account for process variations. In the example of FIG. 2, the capacitance (C_{C}) of the capacitor 210 cannot be trimmed responsive to the input of the buffer 215 being a high voltage terminal. Advantageously, as illustrated in Equation (1), process variations in the capacitance (C_{C}) of the capacitor 210 may be accounted for by adjusting the transconductance constant (K) of the transconductance circuitry 205. Advantageously, the controller 105 can compensate for variations in the magnitude response using the transconductance trim value (TRIM_{K}). Example calibration operations of the amplifier circuitry 110 are further illustrated and described in connection with FIGS. 7, 8A, and 8B.

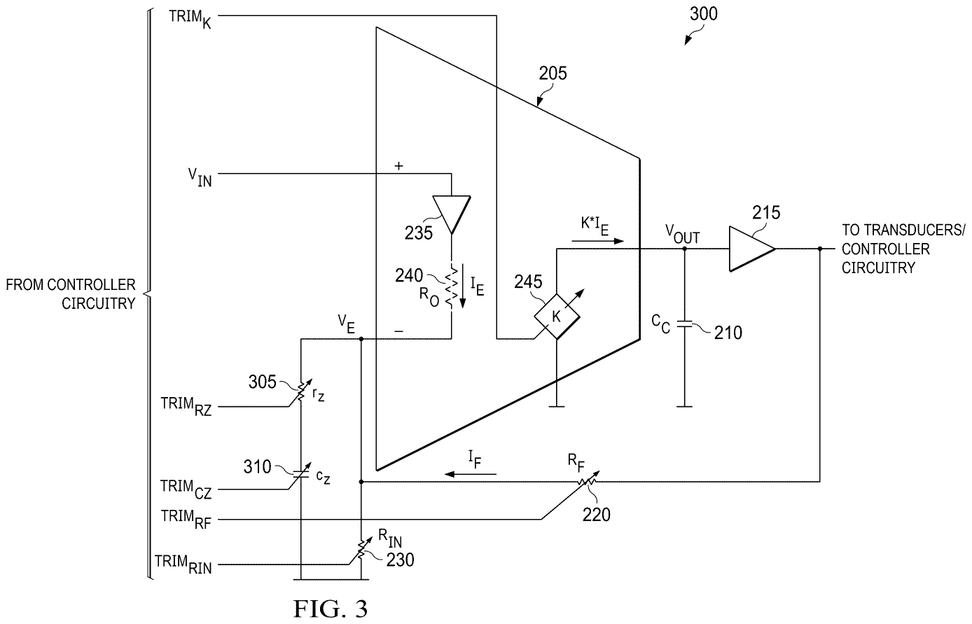

FIG. 3 is a schematic diagram of example amplifier circuitry 300, which is an example of the amplifier circuitry 110 of FIGS. 1 and 2. The example amplifier circuitry 300 of FIG. 3 includes the transconductance circuitry 205, the capacitor 210, the buffer 215, the resistors 220, 230, another example resistor 305, and another example capacitor 310. In some examples, the resistor 305 and the capacitor 310 are referred to as zero-pole pair circuitry.

The amplifier circuitry 300 receives the input voltage (V_{IN}), the transconductance trim value (TRIM_{K}), the input trim value (TRIM_{RIN}), a resistor trim value (TRIM_{RZ}), and a capacitor trim value (TRIM_{CZ}). In some examples, the controller 105 provides the input voltage and trim values. The resistor trim value (TRIM_{RZ}) sets a resistance (R_{Z}) of the resistor 305. The capacitor trim value (TRIM_{CZ}) sets a capacitance (C_{Z}) of the capacitor 310. The amplifier circuitry 300 produces the output signal (V_{OUT}) using the input voltage (V_{IN}).

In the example of FIG. 3, the resistor 220 provides the feedback current (I_{F}) to the resistors 230, 305. The resistors 230, 305 and the capacitor 310 produce the error voltage (V_{E}) responsive to the feedback current (I_{F}). In the example of FIG. 3, the amplifier circuitry 300 utilizes the current feedback path to create a low impedance terminal that provides the error voltage (V_{E}). Such a low impedance terminal may be referred to as a virtual ground. Advantageously, the addition of the resistor 305 and the capacitor 310 at the low impedance terminal does not change the stability of the amplifier circuitry 300.

Unlike the amplifier circuitry 110 of FIG. 2, the amplifier circuitry 300 includes the resistor 305 and the capacitor 310 for relatively high voltage gains, such as output voltage swings greater than twenty volts peak-to-peak. In example operation, as the gain and output voltage of the amplifier circuitry 300 increases, the non-dominant poles of the open-loop gain become overdamped. In such example operations, overdamping the non-dominant poles reduces the closed-loop bandwidth, which reduces the bandwidth of the amplifier circuitry 110 of FIG. 2. Advantageously, the example amplifier circuitry 300 of FIG. 3 uses the resistor 305 and the capacitor 310 to form a pole-zero pair that increases the closed loop bandwidth to support high output voltages.

In example operations, a resistance (R_{Z}) of the resistor 305 and a capacitance (C_{Z}) of the capacitor 310 control the location of a pole. In some examples, the resistor trim value (TRIM_{RZ}) sets the resistance (R_{Z}) of the resistor 305 and the capacitor trim value (TRIM_{CZ}) sets the capacitance (C_{Z}) of the capacitor 310.

In some examples, such as medical implementations, the amplifier circuitry 300 needs to support an increasing bandwidth. For example, in ultrasonic imaging, the amplifier circuitry 300 may need to support a bandwidth of twenty-five megahertz (MHz). In some such examples, the controller 105 may calibrate a frequency response of the amplifier circuitry 300 to satisfy bandwidth requirements.

If the gain of the amplifier circuitry 300 is relatively high, such as substantially greater than unity, the frequency response is a factor of the closed-loop gain. In the example of FIG. 3, the amplifier circuitry 300 has a closed loop gain (LG_{CL}) based on the resistance (R_{F}) of the resistor 220, the capacitance (C_{F}) of the capacitor 225, the resistance (R_{IN}) of the resistor 230, the resistance (R_{Z}) of the resistor 305, the capacitance (C_{Z}) of the capacitor 310, and the open-loop gain (LG_{OP}), which may be determined using Equation (1). In some examples, Equation (2) represents the closed-loop gain of the amplifier circuitry 300 across different frequencies (s).

$$CLOSED LOOP GAIN = {LG}_{CL} = ( 1 + \frac{{R}_{F}}{{R}_{IN}} ) * \frac{1 + {sC}_{Z} {R}_{Z} + {sC}_{Z} {R}_{IN}}{1 + {sC}_{Z} {R}_{Z}} * \frac{{LG}_{OP}}{1 + {LG}_{OP}} ; \qquad Equation ( 2 )$$

In some examples, the controller 105 calibrates the frequency response of the amplifier circuitry 300 using the pole-zero pair of the resistor 305 and the capacitor 310. For example, modifying the factor of the resistances (R_{IN}, R_{Z}) of the resistors 230, 305 shifts the frequency response of the amplifier circuitry 300. Advantageously, as illustrated in Equation (2), frequency response variations in the amplifier circuitry 300 may be accounted for by adjusting the resistances (R_{IN}, R_{Z}) of the resistors 230, 305. Advantageously, the controller 105 can compensate for variations in frequency response using the input trim value (TRIM_{RIN}) and the resistor trim value (TRIM_{RZ}).

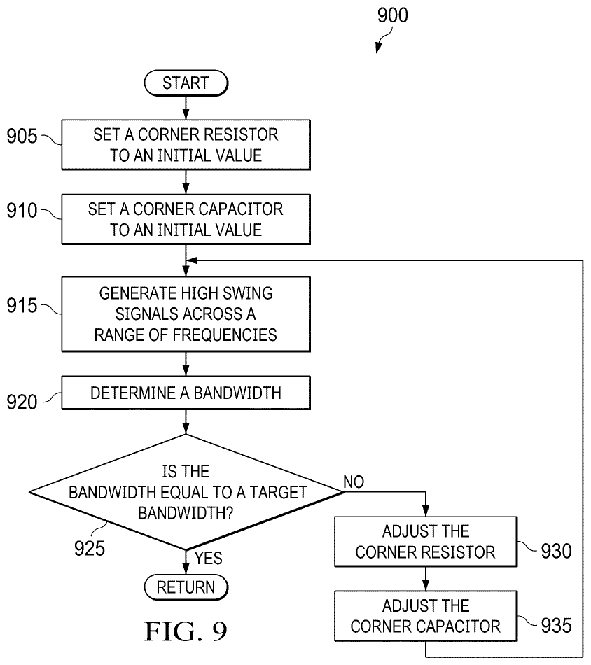

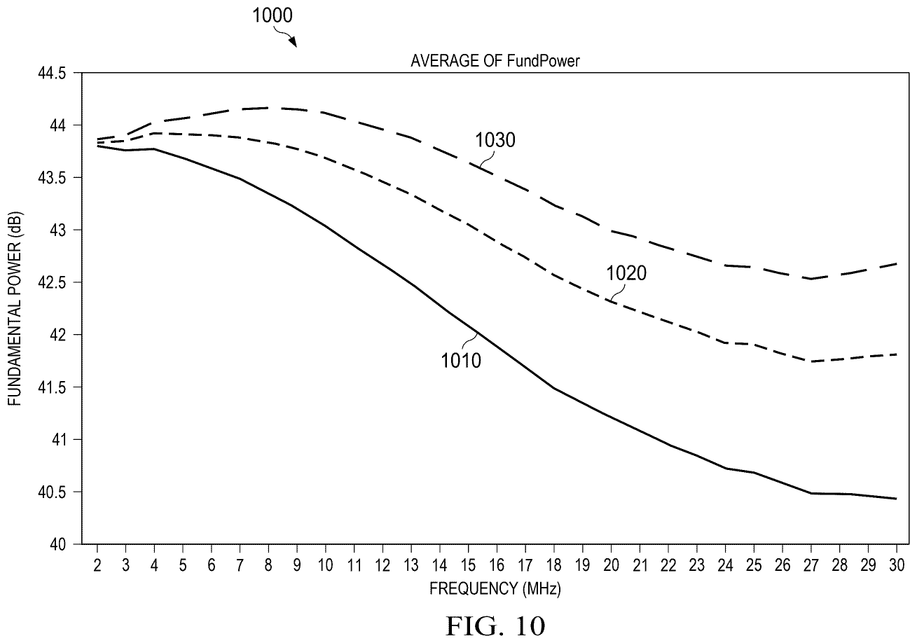

Also, the capacitance (C_{Z}) of the capacitor 310 sets a corner beyond the shifted frequency response. For example, if the bandwidth of the amplifier circuitry 300 is twenty-five megahertz (MHz), the capacitance (C_{Z}) of the capacitor 310 is set to filter frequencies greater than thirty megahertz (MHz). Advantageously, the controller 105 can adjust the capacitor 310 using the capacitor trim value (TRIM_{CZ}). Example calibration operations of the amplifier circuitry 300 are further illustrated and described in connection with FIGS. 9 and 10.

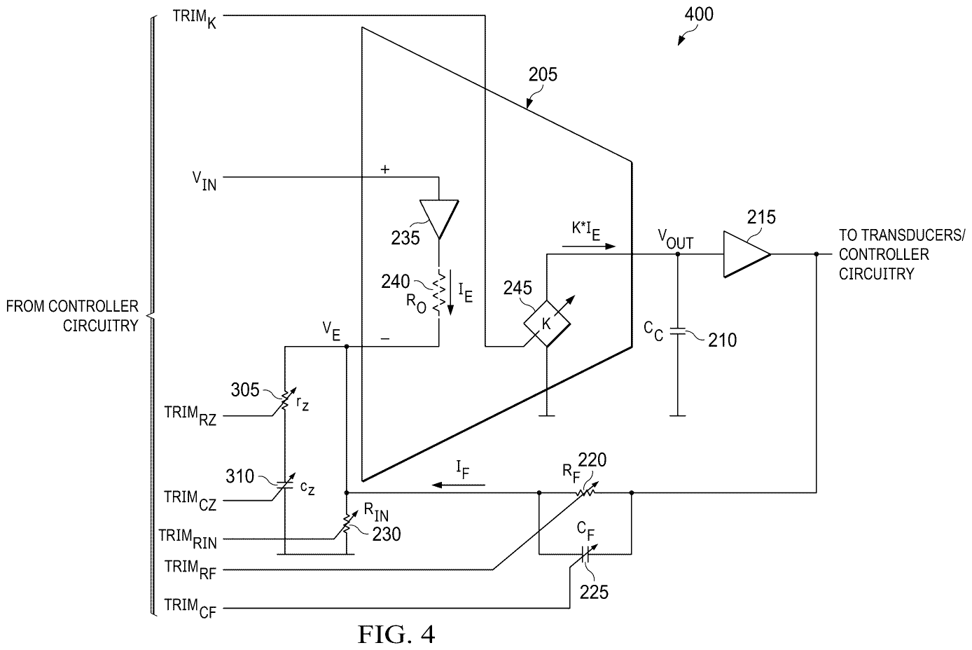

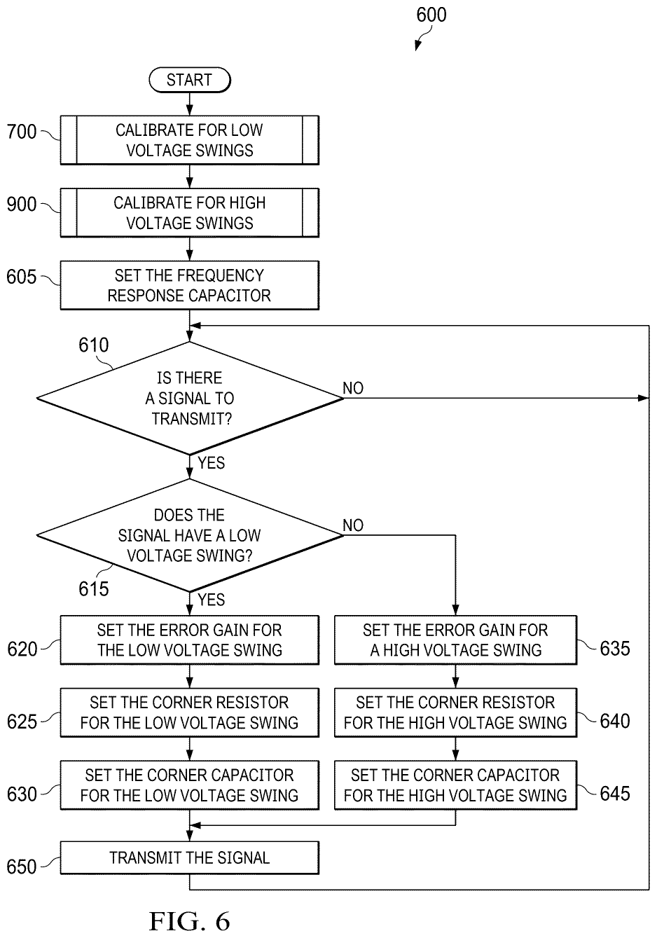

FIG. 4 is a schematic diagram of example amplifier circuitry 400, which is another example of the amplifier circuitry 110, 300 of FIGS. 1, 2, and 3. The example amplifier circuitry 400 of FIG. 4 includes the transconductance circuitry 205, the capacitors 210, 310, the buffer 215, and the resistors 220, 230, 305. In the example of FIG. 4, the amplifier circuitry 400 implements both implementations of the amplifier circuitry 110, 300. For example, the amplifier circuitry 400 includes the capacitor 225 for adjusting the phase margin. Similarly, the amplifier circuitry includes the resistor 305 and the capacitor 310 for adjusting the frequency response. Advantageously, as further described in connection with FIGS. 6, 7, and 9. The controller 105 may use the trim values to calibrate the amplifier circuitry 400 for a wide range of gains across a relatively large bandwidth.

FIG. 5 is a block diagram of an example implementation of the controller 105 of FIG. 1. The controller 105 of FIG. 5 may be instantiated (e.g., creating an instance of, bring into being for any length of time, materialize, implement, etc.) by programmable circuitry such as a Central Processor Unit (CPU) executing first instructions, a field programmable gate array, a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc. Also or alternatively, the controller 105 of FIG. 5 may be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 5 may, thus, be instantiated at the same or different times. Some or all of the circuitry of FIG. 5 may be instantiated, for example, in one or more threads executing concurrently on hardware or in series on hardware. Moreover, in some examples, some or all of the circuitry of FIG. 5 may be implemented by microprocessor circuitry executing instructions or FPGA circuitry performing operations to implement one or more virtual machines or containers. The example controller 105 of FIG. 5 includes example calibration circuitry 505, example signal generator circuitry 510, first example voltage swing circuitry 515, second example voltage swing circuitry 520, an example digital-to-analog converter (DAC) 525, first example trim circuitry 530, second example trim circuitry 535, third example trim circuitry 540, fourth example trim circuitry 545, fifth example trim circuitry 550, and sixth example trim circuitry 555.

The controller 105 receives the output voltage (V_{OUT}) from the amplifier circuitry 110, 300, 400. The controller 105 provides the input voltage (V_{IN}), the transconductance trim value (TRIM_{K}), the input trim value (TRIM_{RIN}), the capacitor trim value (TRIM_{CF}), the resistor trim value (TRIM_{RZ}), and the capacitor trim value (TRIM_{CZ}) to the amplifier circuitry 110, 300, 400. As further described above, the controller 105 controls the transconductance circuitry 205, the capacitors 225, 310, and the resistors 230, 305 using respective ones of the trim values (TRIM_{K}, TRIM_{RIN}, TRIM_{RF}, TRIM_{CF}, TRIM_{RZ}, TRIM_{CZ}). In some examples, the controller 105 provides the trim values (TRIM_{K}, TRIM_{RIN}, TRIM_{RF}, TRIM_{CF}, TRIM_{RZ}, TRIM_{CZ}) at a control input of the transconductance circuitry 205, the capacitors 225, 310, and the resistors 230, 305. In such examples, the control input may be one or more terminals, nodes, inputs, etc., which control at least one of the transconductance factor (K), the capacitance (C_{F}, C_{Z}), or the resistances (R_{IN}, R_{Z}, R_{F}). Alternatively, in some examples, one or more of the transconductance circuitry 205, the capacitors 225, 310, and the resistors 230, 305 may have a set value. In such examples, the value of the one or more of the transconductance circuitry 205, the capacitors 225, 310, and the resistors 230, 305 may be determined using the calibration operations described in connection with FIGS. 7 and 9. Advantageously, the controller 105 may modify one or more of the transconductance circuitry 205, the capacitors 225, 310, and the resistors 230, 305 during run-time.

The calibration circuitry 505 receives the output voltage (V_{OUT}) from the amplifier circuitry 300. The calibration circuitry 505 calibrates the amplifier circuitry 110, 300, 400 by adjusting trim values of the trim circuitry 530, 535, 540, 545, 550. Advantageously, calibrating the amplifier circuitry 110, 300, 400 reduces process variations. In some examples, the calibration circuitry 505 may be illustrated or described external to the controller 105. In such examples, the operations of the calibration circuitry 505 may be performed at a time of manufacture. In some examples, the calibration circuitry 505 is instantiated by programmable circuitry executing calibration instructions to perform operations such as those represented by the flowcharts of FIGS. 6, 7, and 9.

The signal generator circuitry 510 generates digital signals. The signal generator circuitry 510 provides the digital signals to the voltage swing circuitry 515, 520 and the DAC 525. In some examples, such as in the ultrasound system 100 of FIG. 1, the signal generator circuitry 510 generates ultrasonic signals for ultrasound imaging. In some examples, the signal generator circuitry 510 is instantiated by programmable circuitry executing signal generation instructions to perform operations such as those represented by the flowcharts of FIGS. 6, 7, and 9.

The voltage swing circuitry 515 (also referred to as low voltage swing circuitry) monitors signals from the signal generator circuitry 510. The voltage swing circuitry 515 determines if the signal generator circuitry 510 is producing a signal with a relatively low gain, such as a gain near unity. The voltage swing circuitry 515 sets trim values of the trim circuitry 530, 535, 540, 545, 550 for the relatively low gain responsive to a determination that the output of the amplifier circuitry 110, 300, 400 has a voltage swing less than a threshold. In some examples, the voltage swing circuitry 515 is instantiated by programmable circuitry executing swing control instructions to perform operations such as those represented by the flowcharts of FIGS. 6, 7, and 9.

The voltage swing circuitry 520 (also referred to as high voltage swing circuitry) monitors signals from the signal generator circuitry 510. The voltage swing circuitry 520 determines if the signal generator circuitry 510 is producing a signal with a relatively high gain, such as a not near unity. The voltage swing circuitry 520 sets trim values of the trim circuitry 535, 540, 545, 550 for the relatively high gain responsive to a determination that the output of the amplifier circuitry 110, 300, 400 has a voltage swing greater than a threshold. In some examples, the voltage swing circuitry 520 is instantiated by programmable circuitry executing swing control instructions to perform operations such as those represented by the flowcharts of FIGS. 6, 7, and 9.

The DAC 525 receives the digital signal from the signal generator circuitry 510. The DAC 525 converts digital values of the digital signal to produce the input voltage (V_{IN}) of the amplifier circuitry 110, 300, 400. In some examples, the DAC 525 is instantiated by programmable circuitry executing conversion instructions to perform operations such as those represented by the flowcharts of FIGS. 6, 7, and 9.

The trim circuitry 530 provides the capacitor trim value (TRIM_{CF}) to the capacitor 225. The trim circuitry 530 sets the capacitance (C_{F}) of the capacitor 225 using the capacitor trim value (TRIM_{CF}). In some examples, the trim circuitry 530 is a portion of memory, such as a register, location in random access memory (RAM), etc., that stores the capacitor trim value (TRIM_{CF}). In some examples, the trim circuitry 530 is instantiated by programmable circuitry executing trim instructions to perform operations such as those represented by the flowcharts of FIGS. 6, 7, and 9.

The trim circuitry 535 provides the input trim value (TRIM_{RIN}) to the resistor 230. The trim circuitry 535 sets the resistance (RIN) of the resistor 230 using the input trim value (TRIM_{RIN}). In some examples, the trim circuitry 535 is a portion of memory, such as a register, location in random access memory (RAM), etc., that stores the input trim value (TRIM_{RIN}). In some examples, the trim circuitry 535 is instantiated by programmable circuitry executing trim instructions to perform operations such as those represented by the flowcharts of FIGS. 6, 7, and 9.

The trim circuitry 540 provides the capacitor trim value (TRIM_{CZ}) to the capacitor 310. The trim circuitry 540 sets the capacitance (C_{Z}) of the capacitor 310 using the capacitor trim value (TRIM_{CZ}). In some examples, the trim circuitry 540 is a portion of memory, such as a register, location in random access memory (RAM), etc., that stores the capacitor trim value (TRIM_{CZ}). In some examples, the trim circuitry 540 is instantiated by programmable circuitry executing trim instructions to perform operations such as those represented by the flowcharts of FIGS. 6, 7, and 9.

The trim circuitry 545 provides the resistor trim value (TRIM_{RZ}) to the resistor 305. The trim circuitry 545 sets the resistance (R_{Z}) of the resistor 305 using the resistor trim value (TRIM_{RZ}). In some examples, the trim circuitry 545 is a portion of memory, such as a register, location in random access memory (RAM), etc., that stores the resistor trim value (TRIM_{RZ}). In some examples, the trim circuitry 545 is instantiated by programmable circuitry executing trim instructions to perform operations such as those represented by the flowcharts of FIGS. 6, 7, and 9.

The trim circuitry 550 provides the transconductance trim value (TRIM_{K}) to the current source circuitry 245 or more generally the transconductance circuitry 205. The trim circuitry 550 sets the transconductance factor (K) of the transconductance circuitry 205 using the transconductance trim value (TRIM_{K}). In some examples, the trim circuitry 550 is a portion of memory, such as a register, location in random access memory (RAM), etc., that stores the transconductance trim value (TRIM_{K}). In some examples, the trim circuitry 550 is instantiated by programmable circuitry executing trim instructions to perform operations such as those represented by the flowcharts of FIGS. 6, 7, and 9.

The trim circuitry 555 provides the feedback resistor trim value (TRIM_{RF}) to the resistor 220. The trim circuitry 555 sets the resistance (R_{F}) of the resistor 220 using the feedback resistor trim value (TRIM_{RF}). In some examples, the trim circuitry 555 is a portion of memory, such as a register, location in random access memory (RAM), etc., that stores the feedback resistor trim value (TRIM_{RF}). In some examples, the trim circuitry 555 is instantiated by programmable circuitry executing trim instructions to perform operations such as those represented by the flowcharts of FIGS. 6, 7, and 9.

FIG. 6 is a flowchart representative of example machine-readable instructions or example operations 600 that may be at least one of executed, instantiated, or performed using an example implementation of the amplifier circuitry 110, 300, 400 of FIGS. 1, 2, 3, and 4 and the controller 105 of FIGS. 1 and 5 or more generally the ultrasound system 100 of FIG. 1. The example operations 600 begin with example calibration operations 700, 900 of FIGS. 7 and 9.

The example operations 700 of FIG. 7 calibrate the amplifier circuitry 110, 400 for low voltage swings. As described above, when the amplifier circuitry 110, 300, 400 produces signals with low voltage swing conditions (e.g., the gain is near unity), the phase margin is a function of the non-dominate poles of the open-loop gain. Such an open-loop gain of the amplifier circuitry 110, 400 is illustrated by Equation (1). In such examples, the resistor 220 and the capacitor 225 form an additional zero. Also, during the low voltage swing conditions, adjusting the transconductance constant (K) trims the magnitude response, which decides the unity gain bandwidth. In the example operation 700 of FIG. 7, the controller 105 calibrates the capacitance (C_{F}) of the capacitor 225 and the transconductance constant (K) of the transconductance circuitry 205. Advantageously, calibrating the transconductance circuitry 205 and the capacitor 225 changes in the unity gain bandwidth and phase margin resulting from process variations. The example operations 700 are further illustrated and described in connection with FIG. 7.

The example operations 900 of FIG. 9 calibrate the amplifier circuitry 110, 300, 400 for high voltage swings. As described above, when the amplifier circuitry 110, 300, 400 produce signals with high voltage swing conditions (e.g., the gain is not near unity), the non-dominate poles of the open-loop gain are overdamped, which reduces the closed loop bandwidth. In the examples of FIGS. 3 and 4, the resistor 305 and the capacitor 310 add a pole-zero pair, which modifies the closed-loop bandwidth without affecting the open-loop bandwidth. Such a closed-loop gain of the amplifier circuitry 300, 400 is illustrated by Equation (2). In such examples, modifying the factor of Equation (2) formed by the resistances (R_{IN}, R_{Z}) of the resistors 230, 305 shifts the frequency response of the amplifier circuitry 110, 300, 400. Also, adjusting the capacitance (C_{Z}) of the capacitor 310 adds an additional corner beyond the cut-off of the frequency response of the amplifier circuitry 110, 300, 400. For example, the capacitance (C_{Z}) of the capacitor 310 may be set to increase a fall-off of the frequency response beyond a target bandwidth. Advantageously, calibrating the resistor 305 and the capacitor 310 reduces changes in the bandwidth resulting from process variations. The example operations 900 are further illustrated and described in connection with FIG. 9. Control proceeds to Block 605.

The trim circuitry 530 sets the frequency response capacitor. (Block 605). In example operations, the trim circuitry 530 provides the capacitor trim code (TRIM_{CF}), which sets the capacitance (C_{F}) of the capacitor 225. In some examples, the capacitor 225 is referred to as a frequency response capacitor. In such example operations, the capacitance (C_{F}) of the capacitor 225 determines the phase margin of the amplifier circuitry 110, 400 during low voltage conditions. In some devices, such as medical systems, the trim circuitry 530 provides a calibrated capacitor trim code (TRIM_{CF}) to set the phase margin for gains near unity approximately equal across different instances of the amplifier circuitry 110, 300, 400.

The signal generator circuitry 510 determines if there is a signal to transmit. (Block 610). In example operations, the signal generator circuitry 510 generates a digital signal responsive to a determination that the amplifier circuitry 110, 300, 400 is to drive the transducer(s) 115. In some examples, the signal generator circuitry 510 generates the digital signal responsive to an indication from external circuitry, a periodic interval, etc. In such example operations, the DAC 525 generates the input voltage (V_{IN}) of the amplifier circuitry 110, 300, 400 responsive to the digital signal from the signal generator circuitry 510. If the signal generator circuitry 510 determines there is no signal to transmit (e.g., Block 610 returns a result of NO), control proceeds to return to Block 610.

If the signal generator circuitry 510 determines there is a signal to transmit (e.g., Block 610 returns a result of YES), the voltage swing circuitry 515, 520 determines if the signal has a low voltage swing. (Block 615). In example operations, the voltage swing circuitry 515, 520 determines a voltage swing of an output of the amplifier circuitry 110, 300, 400 based on the signal generator circuitry 510. In some examples, the signal generator circuitry 510 provides a gain to the voltage swing circuitry 515, 520. In such examples, the voltage swing circuitry 515, 520 determines the output voltage (V_{OUT}) of the amplifier circuitry 110, 300, 400 will have a low voltage swing for gains near unity. Alternatively, the voltage swing circuitry 515, 520 determines the output voltage (V_{OUT}) of the amplifier circuitry 110, 300, 400 will have a relatively high voltage swing if the gain value is not near unity. In such example operations, the voltage swing circuitry 515 sets the trim values of the trim circuitry 530, 535, 540, 545, 550 responsive to a determination that the amplifier circuitry 110, 300, 400 has a gain near unity. Such a condition is also referred to as low voltage conditions. Similarly, the voltage swing circuitry 520 sets the trim values of the trim circuitry 535, 540, 545, 550 responsive to a determination that the amplifier circuitry 110, 300, 400 has a gain that is not near unity. Advantageously, the voltage swing circuitry 515, 520 dynamically adjust the amplifier circuitry 110, 300, 400 responsive to the gain.

If voltage swing circuitry 515, 520 determines that the signal has a low voltage swing (e.g., Block 615 returns a result of YES), the trim circuitry 550 sets the error gain for the low voltage swing. (Block 620). In some examples, the transconductance factor (K) of the transconductance circuitry 205 is referred to as the error gain. The trim circuitry 545 sets the corner resistor for the low voltage swing. (Block 625). The trim circuitry 540 sets the corner capacitor for the low voltage swing. (Block 630). In example operations, the voltage swing circuitry 515 adjusts the transconductance factor (K) of the transconductance circuitry 205, the resistance (R_{Z}) of the resistor 305, and the capacitance (C_{Z}) of the capacitor 310 for relatively low gains. In some examples, the voltage swing circuitry 515 determines the trim values of the trim circuitry 540, 545, 550 responsive to the example operations 700 of FIG. 7. In other examples, the voltage swing circuitry 515 is provided the trim values of the trim circuitry 540, 545, 550. In such example operations, the resistance (R_{Z}) of the resistor 305 and the capacitance (C_{Z}) of the capacitor 310 are set to reduce an impact on the open-loop gain.

If the voltage swing circuitry 515, 520 determines that the signal does not have a low voltage swing (e.g., Block 615 returns a result of NO), the trim circuitry 550 sets the error gain for a high voltage swing. (Block 635). The trim circuitry 545 sets the corner resistor for the high voltage swing. (Block 640). The trim circuitry 540 sets the corner capacitor for the high voltage swing. (Block 645). In example operations, the voltage swing circuitry 520 adjusts the transconductance factor (K) of the transconductance circuitry 205, the resistance (R_{Z}) of the resistor 305, and the capacitance (C_{Z}) of the capacitor 310 for a relatively high gain. In some examples, the voltage swing circuitry 520 determines the trim values of the trim circuitry 540, 545, 550 responsive to the example operations 900 of FIG. 9. In other examples, the voltage swing circuitry 520 is provided the trim values of the trim circuitry 540, 545, 550.

The amplifier circuitry 110, 300, 400 transmits the signal. (Block 650). As further described in connection with FIGS. 2, 3, and 4, the amplifier circuitry 110, 300, 400 produces the output voltage (V_{OUT}) responsive to the input voltage (V_{IN}) and the trim values (TRIM_{K}, TRIM_{CF}, TRIM_{RIN}, TRIM_{RZ}, TRIM_{CZ}). Advantageously, the controller 105 dynamically adjusts the amplifier circuitry 110, 300, 400 for different operating conditions. Advantageously, in high-precision systems, such as medical devices, the phase margin, and frequency response, which sets the bandwidth, of the amplifier circuitry 110, 300, 400 can be calibrated to account for process variations.

Control proceeds to return to Block 610. Example methods are described with reference to the flowchart illustrated in FIG. 6. However, many other methods of implementing the amplifier circuitry 110, 300, 400 of FIGS. 1, 2, 3, and 4 and the controller 105 of FIGS. 1 and 5 or more generally the ultrasound system 100 of FIG. 1 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 7 is a flowchart representative of example machine-readable instructions or example operations 700 that may be at least one of executed, instantiated, or performed using an example implementation of the controller 105 of FIGS. 1 and 5 to calibrate the amplifier circuitry 110, 300, 400 of FIGS. 1, 2, 3, and 4 for the first voltage swing conditions.

The example operations 700 begin at Block 705 at which the trim circuitry 550 sets an error gain to an initial value. In some examples, the transconductance factor (K) of the transconductance circuitry 205 is referred to as the error gain.

The trim circuitry 530 sets a frequency response capacitor to an initial value. (Block 710). The trim circuitry 545 sets a corner resistor to an initial value. (Block 715). The trim circuitry 540 sets a corner capacitor to an initial value. (Block 720). In example operations, the calibration circuitry 505 initializes low voltage swing calibrations by providing initial trim values to the voltage swing circuitry 515, which adjusts the trim circuitry 530, 535, 540, 545, 550 for the low voltage swing conditions. The voltage swing circuitry 515 sets the trim values of the trim circuitry 530, 535, 540, 545, 550 to the initial values. In some examples, the initial values of the trim circuitry 530, 535, 540, 545, 550 correspond to target values of the transconductance factor (K), the capacitors 225, 310, and the resistors 230, 305. In such examples, the target values may be a result of an empirical calculation of the transconductance factor (K), the capacitors 225, 310, and the resistors 230, 305. For example, a designer determines the transconductance factor (K), the capacitances of the capacitors 225, 310, and the resistances of the resistors 230, 305 to achieve a bandwidth of twenty-five megahertz (MHz). In such examples, the initial trim values correspond to the determined values.

The signal generator circuitry 510 generates low swing signals across a range of frequencies. (Block 725). In example operations, the signal generator circuitry 510 generates a series of digital signals having a gain near unity across a range of frequencies. For example, if a target bandwidth of the amplifier circuitry 110, 300, 400 is twenty-five megahertz (MHz), the signal generator circuitry 510 generates a plurality of signals having frequencies spanning thirty megahertz. In such example operations, the initial values of the trim circuitry 530, 535, 540, 545, 550 ideally set the gain of the amplifier circuitry 110, 300, 400 to unity.

The calibration circuitry 505 determines a unity gain bandwidth. (Block 730). The unity gain bandwidth is the bandwidth of the amplifier circuitry 110, 300, 400 when the gain is one. In example operations, the calibration circuitry 505 monitors the output voltage (V_{OUT}) of the amplifier circuitry 110, 300, 400 responsive to signals across the range of frequencies. In some examples, the calibration circuitry 505 determines the unity gain bandwidth based on the fall-off in power at the output of the amplifier circuitry 110, 300, 400.

The calibration circuitry 505 determines if a unity gain bandwidth is equal to a target bandwidth. (Block 735). In example operations, the calibration circuitry 505 compares the determined unity gain bandwidth to a target unity gain bandwidth. In some examples, the target unity gain bandwidth represents a design specification of the amplifier circuitry 110, 300, 400. For example, the ultrasound system 100 may need the amplifier circuitry 110 to support twenty-five megahertz. In such examples, the target unity gain bandwidth of the amplifier circuitry 110 is twenty-five megahertz.

If the calibration circuitry 505 determines that the unity gain bandwidth is not equal to a target bandwidth (e.g., Block 735 returns a result of NO), the trim circuitry 550 adjusts the error gain. (Block 740). In example operations, the voltage swing circuitry 515 modifies the transconductance trim value (TRIM_{K}) of the trim circuitry 550 responsive to a determination that the unity gain bandwidth is not equal to the target unity gain bandwidth. In some examples, the voltage swing circuitry 515 increases or decreases the transconductance factor (K) of the transconductance circuitry 205 to shift the magnitude response of the amplifier circuitry 110, 400. In such example operations, the trim circuitry 550 changes the transconductance factor (K) of the transconductance circuitry 205 responsive to the modified transconductance trim value. Advantageously, the calibration circuitry 505 continues to adjust the transconductance trim value (TRIM_{K}) until the unity gain bandwidth is approximately equal to the target unity gain bandwidth.

If the calibration circuitry 505 determines that the unity gain bandwidth is equal to a target bandwidth (e.g., Block 735 returns a result of YES), the signal generator circuitry 510 generates low swing signals across a range of frequencies. (Block 745). Similar to the example operations of the Block 725, the signal generator circuitry 510 generates a series of digital signals having a gain near unity across a range of frequencies. In such example operations, the trim circuitry 550 sets the transconductance factor (K) of the transconductance circuitry 205 to produce the target unity gain bandwidth.

The calibration circuitry 505 determines the phase margin. (Block 750). In example operations, the calibration circuitry 505 monitors the output voltage (V_{OUT}) of the amplifier circuitry 110, 300, 400 responsive to signals across the range of frequencies. In some examples, the calibration circuitry 505 determines the phase margin based on the output of the amplifier circuitry 110, 300, 400.

The calibration circuitry 505 determines if the phase margin is equal to a target phase margin. (Block 755). In example operations, the calibration circuitry 505 compares the determined phase margin to a target phase margin. In some examples, the target phase margin represents a design specification of the amplifier circuitry 110, 300, 400. For example, the ultrasound system 100 may need the amplifier circuitry 110 to support twenty-five megahertz. In such examples, the target phase margin of the amplifier circuitry 110 is forty-five degrees.

If the calibration circuitry 505 determines that the phase margin is not equal to the target phase margin (e.g., Block 755 returns a result of NO), the trim circuitry 530 adjusts the frequency response capacitor. (Block 760). In example operations, the voltage swing circuitry 515 modifies the capacitor trim value (TRIM_{CF}) of the trim circuitry 550 responsive to a determination that the phase margin is not equal to the target phase margin. In some examples, the voltage swing circuitry 515 increases or decreases the capacitance (C_{F}) of the capacitor 225 to adjust the phase margin.

If the calibration circuitry 505 determines that the phase margin is equal to the target phase margin (e.g., Block 755 returns a result of YES), control proceeds to return. Example methods are described with reference to the flowchart illustrated in FIG. 7. However, many other methods of calibrating the amplifier circuitry 110, 300, 400 of FIGS. 1, 2, 3, and 4 using the controller 105 of FIGS. 1 and 5 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 8A is a plot 800 of example calibration operations of FIG. 7 for the amplifier circuitry 110, 300, 400 of FIGS. 1, 2, 3, and 4. The example plot 800 of FIG. 8A includes first example measurements 810, second example measurements 820, and third example measurements 830. The measurements 810, 820, 830 represent average fundamental power calculations of the output voltage (V_{OUT}) of the amplifier circuitry 110, 300, 400 during the example frequency sweep of the Block 725. The measurements 810 represent operations if the trim circuitry 550 setting the transconductance factor (K) of the transconductance circuitry 205 to a first transconductance trim value (TRIM_{K_1}). The measurements 820 represent operations if the trim circuitry 550 setting the transconductance factor (K) of the transconductance circuitry 205 to a second transconductance trim value (TRIM_{K_2}). The measurements 830 represent operations if the trim circuitry 550 setting the transconductance factor (K) of the transconductance circuitry 205 to a third transconductance trim value (TRIM_{K_3}). Advantageously, adjusting the transconductance factor (K) modifies the magnitude response of the amplifier circuitry 110, 300, 400 at unity gain. Advantageously, the controller 105 may reduce variations in the magnitude response at unity gain by adjusting the transconductance trim value (TRIM_{K}).

FIG. 8B is a plot 840 of example calibration operations of FIG. 7 for the amplifier circuitry 110, 300, 400 of FIGS. 1, 2, 3, and 4. The example plot 840 of FIG. 8B includes first example measurements 850, second example measurements 860, and third example measurements 870. The measurements 850, 860, 870 represent average fundamental power calculations of the output voltage (V_{OUT}) of the amplifier circuitry 110, 300, 400 during the example frequency sweep of the Block 725. The measurements 850 represent operations if the trim circuitry 530 setting the capacitance (C_{F}) of the capacitor 225 to a first capacitor trim value (TRIM_{CF_1}). The measurements 860 represent operations if the trim circuitry 530 setting the capacitance (C_{F}) of the capacitor 225 to a second capacitor trim value (TRIM_{CF_2}). The measurements 870 represent operations if the trim circuitry 530 setting the capacitance (C_{F}) of the capacitor 225 to a third capacitor trim value (TRIM_{CF_3}). Advantageously, adjusting the capacitance (C_{F}) modifies the phase margin of the amplifier circuitry 110, 300, 400 at relatively low voltage swings, such as voltage swings less than twenty volts peak-to-peak. Advantageously, the controller 105 may reduce variations in the phase margin at unity gain by adjusting the capacitor trim value (TRIM_{CF}).

FIG. 9 is a flowchart representative of example machine-readable instructions or example operations 900 that may be at least one of executed, instantiated, or performed using an example implementation of the controller 105 of FIGS. 1 and 5 to calibrate the amplifier circuitry 110, 300, 400 of FIGS. 1, 2, 3, and 4. The example operations 900 begin at Block 905 at which the trim circuitry 545 sets a corner resistor to an initial value. The trim circuitry 540 sets a corner capacitor to an initial value. (Block 910).

In example operations, the calibration circuitry 505 initializes high voltage swing calibrations by providing initial trim values to the voltage swing circuitry 520, which adjusts the trim circuitry 535, 540, 545, 550 for the high voltage swing conditions. The voltage swing circuitry 520 sets the trim values of the trim circuitry 535, 540, 545, 550 to the initial values. In some examples, the initial values of the trim circuitry 535, 540, 545, 550 correspond to target values of the transconductance factor (K), the resistors 230, 305, and the capacitor 310. In such examples, the target values may be a result of an empirical calculation of the transconductance factor (K), the resistors 230, 305, and the capacitor 310. For example, a designer determines the transconductance factor (K), the resistances of the resistors 230, 305, and the capacitance of the capacitor 310 to achieve a bandwidth of twenty-five megahertz (MHz). In such examples, the initial trim values correspond to the determined values.

The signal generator circuitry 510 generates high swing signals across a range of frequencies. (Block 915). In example operations, the signal generator circuitry 510 generates a series of digital signals having a gain substantially greater than unity across a range of frequencies. For example, if a target bandwidth of the amplifier circuitry 110, 300, 400 is twenty-five megahertz (MHz), the signal generator circuitry 510 generates a plurality of signals having frequencies spanning thirty megahertz. In such example operations, the initial values of the trim circuitry 530, 535, 540, 545, 550 set the gain of the amplifier circuitry 110, 300, 400 to unity.

The calibration circuitry 505 determines a bandwidth. (Block 920). In example operations, the calibration circuitry 505 monitors the output voltage (V_{OUT}) of the amplifier circuitry 110, 300, 400 responsive to signals across the range of frequencies. In some examples, the calibration circuitry 505 determines the bandwidth based on the fall-off in power at the output of the amplifier circuitry 110, 300, 400.

The calibration circuitry 505 determines if the bandwidth is equal to a target bandwidth. (Block 925). In example operations, the calibration circuitry 505 compares the determined bandwidth to a target bandwidth. In some examples, the target bandwidth represents a design specification of the amplifier circuitry 110, 300, 400. For example, the ultrasound system 100 may need the amplifier circuitry 110 to support twenty-five megahertz. In such examples, the target bandwidth of the amplifier circuitry 110 is twenty-five megahertz.

If the calibration circuitry 505 determines if the bandwidth is not equal to the target bandwidth (e.g., Block 925 returns a result of NO), the trim circuitry 545 adjusts the corner resistor. (Block 930). The trim circuitry 540 adjusts the corner capacitor. (Block 935). In example operations, the voltage swing circuitry 520 modifies the capacitor trim value (TRIM_{CZ}) of the trim circuitry 540 and the resistor trim value (TRIM_{RZ}) of the trim circuitry 545 responsive to a determination that the bandwidth is not equal to the target bandwidth. In some examples, the voltage swing circuitry 520 increases or decreases the resistance of the resistor 305 and/or the capacitance of the capacitor 310 to shift the frequency response of the amplifier circuitry 110, 300, 400. In such example operations, the trim circuitry 540 changes the capacitance (C_{Z}) of the capacitor 310 and the trim circuitry 545 changes the resistance (R_{Z}) of the resistor 305 responsive to the new trim values. Advantageously, the calibration circuitry 505 continues to adjust the trim values (TRIM_{RZ}, TRIM_{CZ}) until the bandwidth is approximately equal to the target bandwidth. Control proceeds to return to Block 915.

If the calibration circuitry 505 determines if the bandwidth is equal to the target bandwidth (e.g., Block 925 returns a result of YES), control proceeds to return. Example methods are described with reference to the flowchart illustrated in FIG. 9. However, many other methods of calibrating the amplifier circuitry 110, 300, 400 of FIGS. 1, 2, 3, and 4 using the controller 105 of FIGS. 1 and 5 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 10 is a plot 1000 of example calibration operations of FIG. 9 for the amplifier circuitry 110, 300, 400 of FIGS. 1, 2, 3, and 4. The example plot 1000 of FIG. 10 includes first example measurements 1010, second example measurements 1020, and third example measurements 1030. The measurements 1010, 1020, 1030 represent average fundamental power calculations of the output voltage (V_{OUT}) of the amplifier circuitry 110, 300, 400 during the example frequency sweep of the Block 915. The measurements 1010 represent operations if the trim circuitry 540, 545 sets the resistor 305 and the capacitor 310 using first trim values (TRIM_{RZ_1}, TRIM_{CZ_1}). The measurements 1020 represent operations if the trim circuitry 540, 545 sets the resistor 305 and the capacitor 310 using second trim values (TRIM_{RZ_2}, TRIM_{CZ_2}). The measurements 1030 represent operations if the trim circuitry 540, 545 sets the resistor 305 and the capacitor 310 using third trim values (TRIM_{RZ_3}, TRIM_{CZ_3}). Advantageously, adjusting the resistance (R_{Z}) and the capacitance (C_{Z}) modifies the frequency response of the amplifier circuitry 110, 300, 400 at relatively high gains. Advantageously, the controller 105 may reduce variations in the frequency response by adjusting the trim values (TRIM_{RZ}, TRIM_{CZ}).

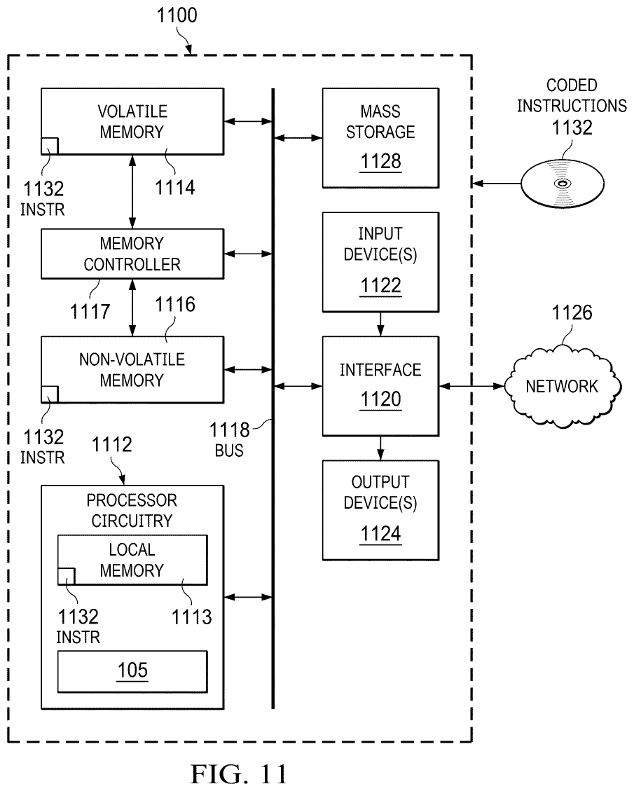

FIG. 11 is a block diagram of an example programmable circuitry platform 1100 structured to one or a combination of execute or instantiate one or more of the example machine-readable instructions or the example operations of FIGS. 6, 7, and 9 to implement the controller 105 of FIGS. 1 and 5. The programmable circuitry platform 1100 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing or electronic device.

The programmable circuitry platform 1100 of the illustrated example includes programmable circuitry 1112. The programmable circuitry 1112 of the illustrated example is hardware. For example, the programmable circuitry 1112 can be implemented by one or more integrated circuits, logic circuits, FPGAs, microprocessors, CPUs, GPUs, DSPs, or microcontrollers from any desired family or manufacturer. The programmable circuitry 1112 may be implemented by one or more semiconductor based (e.g., silicon based) devices. In this example, the programmable circuitry 1112 implements the controller 105 of FIGS. 1 and 5.

The programmable circuitry 1112 of the illustrated example includes a local memory 1113 (e.g., a cache, registers, etc.). The programmable circuitry 1112 of the illustrated example is in communication with main memory 1114, 1116, which includes a volatile memory 1114 and a non-volatile memory 1116, by a bus 1118. The volatile memory 1114 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 1116 may be implemented by one or a combination of flash memory or any other desired type of memory device. Access to the main memory 1114, 1116 of the illustrated example is controlled by a memory controller 1117. In some examples, the memory controller 1117 may be implemented by one or more integrated circuits, logic circuits, microcontrollers from any desired family or manufacturer, or any other type of circuitry to manage the flow of data going to and from the main memory 1114, 1116.

The programmable circuitry platform 1100 of the illustrated example also includes interface circuitry 1120. The interface circuitry 1120 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1122 are connected to the interface circuitry 1120. The input device(s) 1122 permit(s) a user (e.g., a human user, a machine user, etc.) to enter one of or a combination of data or commands into the programmable circuitry 1112. The input device(s) 1122 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 1124 are also connected to the interface circuitry 1120 of the illustrated example. The output device(s) 1124 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 1120 of the illustrated example, thus, includes one of or a combination of a graphics driver card, a graphics driver chip, or graphics processor circuitry such as a GPU.

The interface circuitry 1120 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 1126. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1100 of the illustrated example also includes one or more mass storage discs or devices 1128 to store one or more of firmware, software, or data. Examples of such mass storage discs or devices 1128 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 1132, which may be implemented by the machine-readable instructions of FIGS. 6, 7, and 9, may be stored in one of or a combination of the mass storage device 1128, in the volatile memory 1114, in the non-volatile memory 1116, or on at least one non-transitory computer readable storage medium such as a CD or DVD which may be removable.

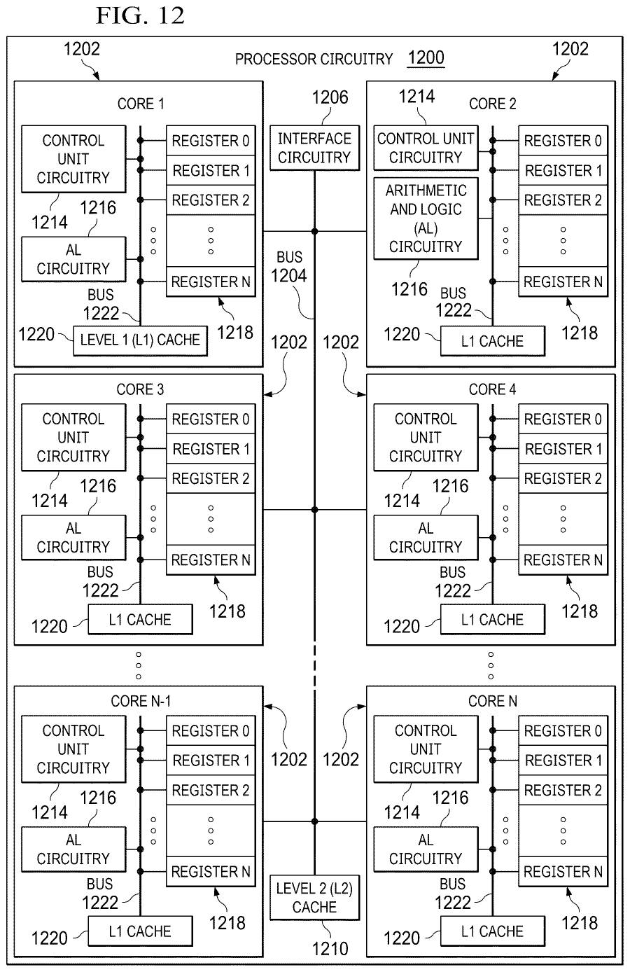

FIG. 12 is a block diagram of an example implementation of the programmable circuitry 1112 of FIG. 11. In this example, the programmable circuitry 1112 of FIG. 11 is implemented by a microprocessor 1200. For example, the microprocessor 1200 may be a general-purpose microprocessor (e.g., general-purpose microprocessor circuitry). The microprocessor 1200 executes some or all of the machine-readable instructions of the flowcharts of FIGS. 6, 7, and 9 to effectively instantiate the circuitry of FIG. 5 as logic circuits to perform operations corresponding to those machine-readable instructions. In some such examples, the circuitry of FIG. 5 is instantiated by the hardware circuits of the microprocessor 1200 in combination with the machine-readable instructions. For example, the microprocessor 1200 may be implemented by multi-core hardware circuitry such as a CPU, a DSP, a GPU, an XPU, etc. Although it may include any number of example cores 1202 (e.g., 1 core), the microprocessor 1200 of this example is a multi-core semiconductor device including N cores.

The cores 1202 of the microprocessor 1200 may operate independently or may cooperate to execute machine-readable instructions. For example, machine code corresponding to a firmware program, an embedded software program, or a software program may be executed by one of the cores 1202 or may be executed by multiple ones of the cores 1202 at the same or different times. In some examples, the machine code corresponding to the firmware program, the embedded software program, or the software program is split into threads and executed in parallel by two or more of the cores 1202. The software program may correspond to a portion or all of the machine-readable instructions or operations represented by the flowcharts of FIGS. 6, 7, and 9.

The cores 1202 may communicate by a first example bus 1204. In some examples, the first bus 1204 may be implemented by a communication bus to effectuate communication associated with one(s) of the cores 1202. For example, the first bus 1204 may be implemented by at least one of an Inter-Integrated Circuit (I2C) bus, a Serial Peripheral Interface (SPI) bus, a PCI bus, or a PCIe bus. Also or alternatively, the first bus 1204 may be implemented by any other type of computing or electrical bus. The cores 1202 may receive data, instructions, and signals from one or more external devices by example interface circuitry 1206. The cores 1202 may output data, instructions, and signals to the one or more external devices by the interface circuitry 1206. Although the cores 1202 of this example include example local memory 1220 (e.g., Level 1 (L1) cache that may be split into an L1 data cache and an L1 instruction cache), the microprocessor 1200 also includes example shared memory 1210 that may be shared by the cores (e.g., Level 2 (L2 cache)) for high-speed access to data and instructions. Data and instructions may be transferred (e.g., shared) by one of or a combination of writing to or reading from the shared memory 1210. The local memory 1220 of each of the cores 1202 and the shared memory 1210 may be part of a hierarchy of storage devices including multiple levels of cache memory and the main memory (e.g., the main memory 1114, 1116 of FIG. 11). In some examples, higher levels of memory in the hierarchy exhibit lower access time and have smaller storage capacity than lower levels of memory. Changes in the various levels of the cache hierarchy are managed (e.g., coordinated) by a cache coherency policy.

Each core 1202 may be referred to as a CPU, DSP, GPU, etc., or any other type of hardware circuitry. Each core 1202 includes control unit circuitry 1214, arithmetic and logic (AL) circuitry (sometimes referred to as an ALU) 1216, a plurality of registers 1218, the local memory 1220, and a second example bus 1222. Other structures may be present. For example, each core 1202 may include vector unit circuitry, single instruction multiple data (SIMD) unit circuitry, load/store unit (LSU) circuitry, branch/jump unit circuitry, floating-point unit (FPU) circuitry, etc. The control unit circuitry 1214 includes semiconductor-based circuits structured to control (e.g., coordinate) data movement within the corresponding core 1202. The AL circuitry 1216 includes semiconductor-based circuits structured to perform one or more mathematic or logic operations on the data within the corresponding core 1202. The AL circuitry 1216 of some examples performs integer-based operations. In other examples, the AL circuitry 1216 also performs floating-point operations. In yet other examples, the AL circuitry 1216 may include first AL circuitry that performs integer-based operations and second AL circuitry that performs floating-point operations. In some examples, the AL circuitry 1216 may be referred to as an Arithmetic Logic Unit (ALU).

The registers 1218 are semiconductor-based structures to store data and instructions such as results of one or more of the operations performed by the AL circuitry 1216 of the corresponding core 1202. For example, the registers 1218 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1218 may be arranged in a bank as shown in FIG. 12. Alternatively, the registers 1218 may be organized in any other arrangement, format, or structure, such as by being distributed throughout the core 1202 to shorten access time. The second bus 1222 may be implemented by at least one of an I2C bus, a SPI bus, a PCI bus, or a PCIe bus.

Each core 1202 or, more generally, the microprocessor 1200 may include additional or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) or other circuitry may be present. The microprocessor 1200 is a semiconductor device fabricated to include many transistors interconnected to implement the structures described above in one or more integrated circuits (ICs) contained in one or more packages.

The microprocessor 1200 may include or cooperate with one or more accelerators (e.g., acceleration circuitry, hardware accelerators, etc.). In some examples, accelerators are implemented by logic circuitry to perform certain tasks more quickly and efficiently than can be done by a general-purpose processor. Examples of accelerators include ASICs and FPGAs such as those described herein. A GPU, DSP, or other programmable device can also be an accelerator. Accelerators may be on-board the microprocessor 1200, in the same chip package as the microprocessor 1200, or in one or more separate packages from the microprocessor 1200.

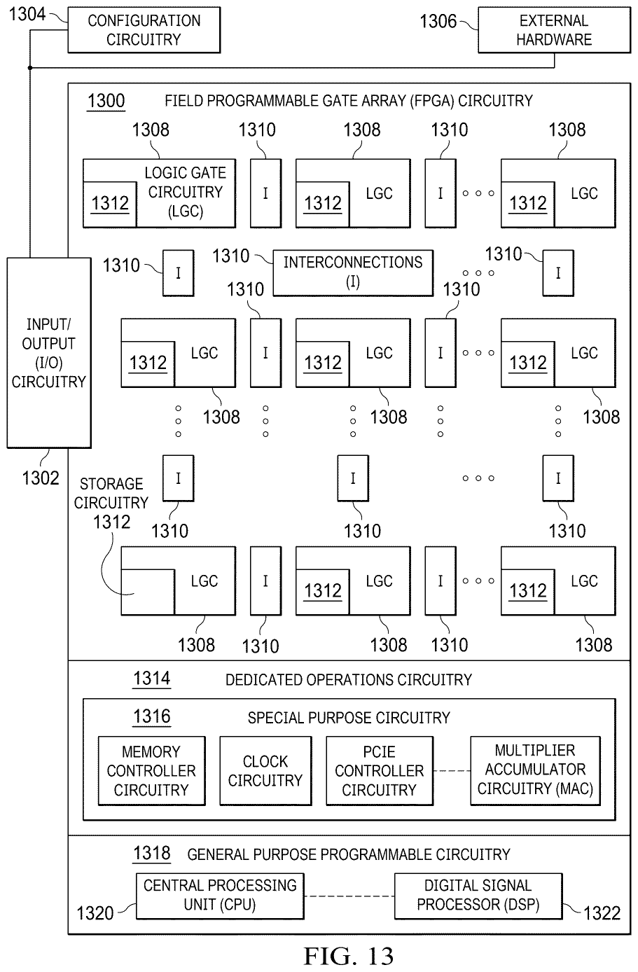

FIG. 13 is a block diagram of another example implementation of the programmable circuitry 1112 of FIG. 11. In this example, the programmable circuitry 1112 is implemented by FPGA circuitry 1300. For example, the FPGA circuitry 1300 may be implemented by an FPGA. The FPGA circuitry 1300 can be used, for example, to perform operations that could otherwise be performed by the example microprocessor 1200 of FIG. 12 executing corresponding machine-readable instructions. However, once configured, the FPGA circuitry 1300 instantiates the operations and functions corresponding to the machine-readable instructions in hardware and, thus, can often execute the operations/functions faster than they could be performed by a general-purpose microprocessor executing the corresponding software.

More specifically, in contrast to the microprocessor 1200 of FIG. 12 described above (which is a general purpose device that may be programmed to execute some or all of the machine-readable instructions represented by the flowcharts of FIGS. 6, 7, and 9 but whose interconnections and logic circuitry are fixed once fabricated), the FPGA circuitry 1300 of the example of FIG. 13 includes interconnections and logic circuitry that may be one of or a combination of configured, structured, programmed, and interconnected in different ways after fabrication to instantiate, for example, some or all of the operations/functions corresponding to the machine-readable instructions represented by the flowcharts of FIGS. 6, 7, and 9. In particular, the FPGA circuitry 1300 may be thought of as an array of logic gates, interconnections, and switches. The switches can be programmed to change how the logic gates are interconnected by the interconnections, effectively forming one or more dedicated logic circuits (unless and until the FPGA circuitry 1300 is reprogrammed). The configured logic circuits enable the logic gates to cooperate in different ways to perform different operations on data received by input circuitry. Those operations may correspond to some or all of the instructions (e.g., the software and/or firmware) represented by the flowcharts of FIGS. 6, 7, and 9. As such, the FPGA circuitry 1300 may be at least one of configured or structured to effectively instantiate some or all of the operations/functions corresponding to the machine-readable instructions of the flowchart(s) of FIGS. 6, 7, and 9 as dedicated logic circuits to perform the operations/functions corresponding to those software instructions in a dedicated manner analogous to an ASIC. Therefore, the FPGA circuitry 1300 may perform the operations/functions corresponding to the some or all of the machine-readable instructions of FIGS. 6, 7, and 9 faster than the general-purpose microprocessor can execute the same.

In the example of FIG. 13, the FPGA circuitry 1300 is at least one of configured or structured in response to being programmed (and/or reprogrammed one or more times) based on a binary file. In some examples, the binary file may be one of or both of compiled or generated based on instructions in a hardware description language (HDL) such as Lucid, Very High-Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1300 of FIG. 13 may at least one of access or load the binary file to the FPGA circuitry 1300 of FIG. 13 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1300 of FIG. 13 to at least one of configure or structure the FPGA circuitry 1300 of FIG. 13, or portion(s) thereof.

In some examples, the binary file is at least one of compiled, generated, transformed, or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is at least one of compiled, generated, or otherwise output from the uniform software platform based on the second instructions. In some examples, the FPGA circuitry 1300 of FIG. 13 may at least one of access or load the binary file to the FPGA circuitry 1300 of FIG. 13 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1300 of FIG. 13 to at least one of configure or structure the FPGA circuitry 1300 of FIG. 13, or portion(s) thereof.

The FPGA circuitry 1300 of FIG. 13, includes example input/output (I/O) circuitry 1302 to at least one of receive or output data to/from at least one of example configuration circuitry 1304 or external hardware 1306. For example, the configuration circuitry 1304 may be implemented by interface circuitry that may receive a binary file, which may be implemented by one or more of a bit stream, data, or machine-readable instructions, to configure the FPGA circuitry 1300, or portion(s) thereof. In some such examples, the configuration circuitry 1304 may receive the binary file from one of or a combination of a user, a machine (e.g., hardware circuitry (e.g., programmable or dedicated circuitry) that may implement an Artificial Intelligence/Machine Learning (AI/ML) model to generate the binary file, etc.), or any combination(s) thereof). In some examples, the external hardware 1306 may be implemented by external hardware circuitry. For example, the external hardware 1306 may be implemented by the microprocessor 1200 of FIG. 12.

The FPGA circuitry 1300 also includes an array of example logic gate circuitry 1308, a plurality of example configurable interconnections 1310, and example storage circuitry 1312. The logic gate circuitry 1308 and the configurable interconnections 1310 are configurable to instantiate one or more operations/functions that may correspond to at least some of the machine-readable instructions of FIGS. 6, 7, and 9 and/or other desired operations. The logic gate circuitry 1308 shown in FIG. 13 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1308 to enable configuration of one of or a combination of the electrical structures or the logic gates to form circuits to perform desired operations/functions. The logic gate circuitry 1308 may include other electrical structures such as look-up tables (LUTs), registers (e.g., flip-flops or latches), multiplexers, etc.

The configurable interconnections 1310 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1308 to program desired logic circuits.

The storage circuitry 1312 of the illustrated example is structured to store result(s) of the one or more of the operations performed by corresponding logic gates. The storage circuitry 1312 may be implemented by registers or the like. In the illustrated example, the storage circuitry 1312 is distributed amongst the logic gate circuitry 1308 to facilitate access and increase execution speed.

The example FPGA circuitry 1300 of FIG. 13 also includes example dedicated operations circuitry 1314. In this example, the dedicated operations circuitry 1314 includes special purpose circuitry 1316 that may be invoked to implement commonly used functions to avoid the need to program those functions in the field. Examples of such special purpose circuitry 1316 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1300 may also include example general purpose programmable circuitry 1318 such as an example CPU 1320 or an example DSP 1322. Other general purpose programmable circuitry 1318 may also or alternatively be present such as a GPU, an XPU, etc., that can be programmed to perform other operations.

Although FIGS. 12 and 13 illustrate two example implementations of the programmable circuitry 1112 of FIG. 11, many other approaches are contemplated. For example, FPGA circuitry may include an on-board CPU, such as one or more of the example CPU 1320 of FIG. 12. Therefore, the programmable circuitry 1112 of FIG. 11 may also be implemented by combining at least the example microprocessor 1200 of FIG. 12 and the example FPGA circuitry 1300 of FIG. 13. In some such hybrid examples, one or more cores 1202 of FIG. 12 may execute a first portion of the machine-readable instructions represented by the flowchart(s) of FIGS. 6, 7, and 9 to perform first operation(s)/function(s), the FPGA circuitry 1300 of FIG. 13 may be at least one of configured or structured to perform second operation(s)/function(s) corresponding to a second portion of the machine-readable instructions represented by the flowcharts of FIGS. 6, 7, and 9, and/or an ASIC may be at least one of configured or structured to perform third operation(s)/function(s) corresponding to a third portion of the machine-readable instructions represented by the flowcharts of FIGS. 6, 7, and 9.

Some or all of the circuitry of FIG. 5 may, thus, be instantiated at the same or different times. For example, same and/or different portion(s) of the microprocessor 1200 of FIG. 12 may be programmed to execute portion(s) of machine-readable instructions at the same and/or different times. In some examples, same and/or different portion(s) of the FPGA circuitry 1300 of FIG. 13 may be at least one of configured or structured to perform operations/functions corresponding to portion(s) of machine-readable instructions at the same and/or different times.

In some examples, some or all of the circuitry of FIG. 5 may be instantiated, for example, in one or more threads executing concurrently and/or in series. For example, the microprocessor 1200 of FIG. 12 may execute machine-readable instructions in one or more threads executing concurrently and/or in series. In some examples, the FPGA circuitry 1300 of FIG. 13 may be at least one of configured or structured to carry out operations/functions concurrently and/or in series. Moreover, in some examples, some or all of the circuitry of FIG. 5 may be implemented within one or more virtual machines or containers executing on the microprocessor 1200 of FIG. 12.

In some examples, the programmable circuitry 1112 of FIG. 11 may be in one or more packages. For example, at least one of the microprocessor 1200 of FIG. 12 or the FPGA circuitry 1300 of FIG. 13 may be in one or more packages. In some examples, an XPU may be implemented by the programmable circuitry 1112 of FIG. 11, which may be in one or more packages. For example, the XPU may include a CPU (e.g., the microprocessor 1200 of FIG. 12, the CPU 1320 of FIG. 13, etc.) in one package, a DSP (e.g., the DSP 1322 of FIG. 13) in another package, a GPU in yet another package, and an FPGA (e.g., the FPGA circuitry 1300 of FIG. 13) in still yet another package.

While an example manner of implementing the controller 105 of FIG. 1 is illustrated in FIG. 5, one or more of the elements, processes, or devices illustrated in FIG. 5 may be combined, divided, re-arranged, omitted, eliminated, or implemented in any other way. Further, the controller 105 of FIGS. 1 and 5, may be implemented by hardware alone or by hardware in combination with software and firmware. Thus, for example, any portion of the controller 105 of FIGS. 1 and 5, or, more generally, the example controller 105 of FIGS. 1 and 5, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example controller 105 of FIGS. 1 and 5 may include one or more elements, processes, or devices in addition to, or instead of, those illustrated in FIG. 5, or may include more than one of any or all of the illustrated elements, processes and devices.

Flowchart(s) representative of example machine-readable instructions, which may be executed by programmable circuitry to at least one of implement or instantiate the controller 105 of FIGS. 1 and 5 or representative of example operations which may be performed by programmable circuitry to at least one of implement or instantiate the controller 105 of FIGS. 1 and 5, are shown in FIGS. 6, 7, and 9. The machine-readable instructions may be one or more executable programs or portion(s) of one or more executable programs for execution by programmable circuitry such as the programmable circuitry 1112 shown in the example processor platform 1100 described below in connection with FIG. 11 and may be one or more function(s) or portion(s) of functions to be performed by the example programmable circuitry (e.g., an FPGA) described below in connection with FIG. 12 or 13. In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 6, 7, and 9, many other methods of implementing the example controller 105 of FIGS. 1 and 5 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). As used herein, programmable circuitry includes any type(s) of circuitry that may be programmed to perform a desired function such as, for example, one of or a combination of a CPU or an FPGA. The programmable circuitry may include one or more CPUs and/or one or more FPGAs located in the same package (e.g., the same integrated circuit (IC) package or in two or more separate housings), one or more CPUs or FPGAs in a single machine, one or multiple CPUs or FPGAs distributed across multiple servers of a server rack, multiple processors distributed across one or more server racks. Also or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., or any combination(s) thereof in any of the contexts described above.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to have them be directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIGS. 6, 7, and 9 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B.

As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein, integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

What is claimed is:

1. An apparatus comprising:
transconductance circuitry having an input and an output;
a first capacitor having a terminal;
an amplifier having an input and an output, the input of the amplifier coupled to the output of the transconductance circuitry and the terminal of the first capacitor;
a resistor having a first terminal and a second terminal; and
a second capacitor having a first terminal and a second terminal, the first terminal of the second capacitor coupled to the output of the amplifier and the first terminal of the resistor, the second terminal of the second capacitor coupled to the input of the transconductance circuitry and the second terminal of the resistor.

2. The apparatus of claim 1, wherein the amplifier is a first amplifier, the resistor is a first resistor, and the transconductance circuitry includes:
a second amplifier having an output;
a second resistor having a first terminal and a second terminal, the first terminal of the second resistor coupled to the output of the second amplifier, the second terminal of the second resistor coupled to the second terminal of the first resistor and the second terminal of the second capacitor; and
current source circuitry having an output coupled to the terminal of the first capacitor and the input of the first amplifier.

3. The apparatus of claim 1, wherein the resistor is a first resistor, and the apparatus further comprising a second resistor having a terminal coupled to the input of the transconductance circuitry, the second terminal of the first resistor, and the second terminal of the second capacitor.

4. The apparatus of claim 3, further comprising:
a third resistor having a first terminal and a second terminal, the first terminal of the third resistor coupled to the input of the transconductance circuitry, the second terminal of the first resistor, the second terminal of the second capacitor, and the terminal of the second resistor; and
a third capacitor having a terminal coupled to the second terminal of the third resistor.

5. The apparatus of claim 1, wherein the input of the transconductance circuitry is a first input, the transconductance circuitry further has a second input and a control input, the second capacitor further has a control input, and the apparatus further comprising controller circuitry having a first output, a second output, and a third output, the first output of the controller circuitry coupled to the second input of the transconductance circuitry, the second output of the controller circuitry coupled to the control input of the transconductance circuitry, the third output of the controller circuitry coupled to the control input of the second capacitor.

6. The apparatus of claim 5, wherein the controller circuitry includes:
signal generator circuitry having an output;
a digital-to-analog converter (DAC) having an input and an output, the output of the DAC coupled to the second input of the transconductance circuitry;
first voltage swing circuitry having an input and an output; and
second voltage swing circuitry having an input and an output, the input of the second voltage swing circuitry coupled to the output of the signal generator circuitry, the input of the DAC, and the input of the first voltage swing circuitry, the output of the second voltage swing circuitry coupled to the output of the first voltage swing circuitry and the control input of the transconductance circuitry.

7. The apparatus of claim 1, further comprising:
transducers having a terminal;
switch circuitry having a first terminal and a second terminal, the first terminal of the switch circuitry coupled to the output of the amplifier, the first terminal of the resistor, the first terminal of the second capacitor, and the transducers; and
analog front end (AFE) circuitry having an input coupled to the second terminal of the switch circuitry.

8. An apparatus comprising:
transconductance circuitry having an input and an output;
a first capacitor having a terminal;
an amplifier having an input and an output, the input of the amplifier coupled to the output of the transconductance circuitry and the terminal of the first capacitor;
a first resistor having a first terminal and a second terminal, the first terminal of the first resistor coupled to the output of the amplifier;
a second resistor having a terminal;
a third resistor having a first terminal and a second terminal, the first terminal of the third resistor coupled to the input of the transconductance circuitry, the second terminal of the first resistor, and the terminal of the second resistor; and
a second capacitor having a terminal coupled to the second terminal of the third resistor.

9. The apparatus of claim 8, wherein the amplifier is a first amplifier, and the transconductance circuitry includes:
a second amplifier having an output;
a fourth resistor having a first terminal and a second terminal, the first terminal of the fourth resistor coupled to the output of the second amplifier, the second terminal of the fourth resistor coupled to the second terminal of the first resistor, the terminal of the second resistor, and the first terminal of the third resistor; and
current source circuitry having an output coupled to the terminal of the first capacitor and the input of the first amplifier.

10. The apparatus of claim 8, further comprising a third capacitor having a first terminal and a second terminal, the first terminal of the third capacitor coupled to the output of the amplifier and the first terminal of the first resistor, the second terminal of the third capacitor coupled to the second terminal of the first resistor, the terminal of the second resistor, and the first terminal of the third resistor.

11. The apparatus of claim 8, wherein the input of the transconductance circuitry is a first input, the transconductance circuitry further has a second input and a control input, the third resistor further has a control input, the second capacitor further has a control input, and the apparatus further comprising controller circuitry having a first output, a second output, a third output, and a fourth output, the first output of the controller circuitry coupled to the second input of the transconductance circuitry, the second output of the controller circuitry coupled to the control input of the transconductance circuitry, the third output of the controller circuitry coupled to the control input of the third resistor, the fourth output of the controller circuitry coupled to the control input of the second capacitor.

12. The apparatus of claim 11, wherein the controller circuitry includes:
signal generator circuitry having an output;
a digital-to-analog converter (DAC) having an input and an output, the output of the DAC coupled to the second input of the transconductance circuitry;
first voltage swing circuitry having an input and an output; and
second voltage swing circuitry having an input and an output, the input of the second voltage swing circuitry coupled to the output of the signal generator circuitry, the input of the DAC, and the input of the first voltage swing circuitry, the output of the second voltage swing circuitry coupled to the output of the first voltage swing circuitry and the control input of the transconductance circuitry.

13. The apparatus of claim 8, further comprising:
transducers having a terminal;
switch circuitry having a first terminal and a second terminal, the first terminal of the switch circuitry coupled to the output of the amplifier, the first terminal of the first resistor, the first terminal of the second capacitor, and the transducers; and
analog front end (AFE) circuitry having an input coupled to the second terminal of the switch circuitry.

14. An apparatus comprising:
transconductance circuitry having an input and an output;
an amplifier having an input and an output, the input of the amplifier coupled to the output of the transconductance circuitry;
a first resistor having a first terminal and a second terminal;
a first capacitor having a first terminal and a second terminal, the first terminal of the first capacitor coupled to the output of the amplifier and the first terminal of the first resistor;
a second resistor having a first terminal and a second terminal, the first terminal of the second resistor coupled to the input of the transconductance circuitry, the second terminal of the first resistor, and the second terminal of the first capacitor; and
a second capacitor having a terminal coupled to the second terminal of the second resistor.

15. The apparatus of claim 14, further comprising a third capacitor having a terminal coupled to the output of the transconductance circuitry and the input of the amplifier.

16. The apparatus of claim 15, wherein the amplifier is a first amplifier, and the transconductance circuitry includes:
a second amplifier having an output;
a third resistor having a first terminal and a second terminal, the first terminal of the third resistor coupled to the output of the second amplifier, the second terminal of the third resistor coupled to the second terminal of the first resistor and the first terminal of the second resistor; and
current source circuitry having an output coupled to the terminal of the third capacitor and the input of the first amplifier.

17. The apparatus of claim 14, further comprising a third resistor having a terminal coupled to the input of the transconductance circuitry, the second terminal of the first resistor, the second terminal of the first capacitor, and the first terminal of the second resistor.

18. The apparatus of claim 14, wherein the input of the transconductance circuitry is a first input, the transconductance circuitry further has a second input and a control input, the second resistor further has a control input, the second capacitor further has a control input, and the apparatus further comprising controller circuitry having a first output, a second output, a third output, and a fourth output, the first output of the controller circuitry coupled to the second input of the transconductance circuitry, the second output of the controller circuitry coupled to the control input of the transconductance circuitry, the third output of the controller circuitry coupled to the control input of the second resistor, the fourth output of the controller circuitry coupled to the control input of the second capacitor.

19. The apparatus of claim 18, wherein the controller circuitry includes:
signal generator circuitry having an output;
a digital-to-analog converter (DAC) having an input and an output, the output of the DAC coupled to the second input of the transconductance circuitry;
first voltage swing circuitry having an input, a first output, a second output, and a third output; and
second voltage swing circuitry having an input, a first output, a second output, and a third output, the input of the second voltage swing circuitry coupled to the output of the signal generator circuitry, the input of the DAC, and the input of the first voltage swing circuitry, the first output of the second voltage swing circuitry coupled to the first output of the first voltage swing circuitry and the control input of the transconductance circuitry, the second output of the second voltage swing circuitry coupled to the second output of the first voltage swing circuitry and the control input of the second resistor, the third output of the second voltage swing circuitry coupled to the third output of the first voltage swing circuitry and the control input of the second capacitor.

20. The apparatus of claim 14, further comprising:
transducers having a terminal;
switch circuitry having a first terminal and a second terminal, the first terminal of the switch circuitry coupled to the output of the amplifier, the first terminal of the first resistor, the first terminal of the first capacitor, and the transducers; and
analog front end (AFE) circuitry having an input coupled to the second terminal of the switch circuitry.
